(19) United States
(12) Patent Application Publication
(10) Pub. No.: US 2013/0277831 A1
(43) Pub. Date: Oct. 24, 2013

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: SUNG-HWAN YOON, Asan-si (KR); SANG-WOOK PARK, Cheonan-si (KR); HYEONG-SEOB KIM, Cheonan-si (KR)

(73) Assignee: SAMSUNG ELECTRONICS CO., LTD., Suwon-si (KR)

(21) Appl. No.: 13/688,541

(22) Filed: Nov. 29, 2012

(30) Foreign Application Priority Data
Apr. 19, 2012 (KR) 10-2012-0041167

(51) Int. Cl. H01L 23/498

(52) U.S. Cl. CPC H01L 23/49811
USPC 257/737

(57) ABSTRACT

A semiconductor package including a circuit board including a plurality of pads; a support structure disposed on the circuit board; and a plurality of semiconductor chips stacked on the circuit board and the support structure, each semiconductor chip including at least one pad. For each semiconductor chip, the at least one pad is aligned with a corresponding pad of the circuit board; and an electrical connection is formed between the at least one pad and the corresponding pad of the circuit board through the support structure.

### CROSS-REFERENCE TO RELATED APPLICATION

This application claims priority under 35 U.S.C. §119 to Korean Patent Application No. 10-2012-0041167 filed on Apr. 19, 2012, the disclosure of which is hereby incorporated by reference in its entirety.

### BACKGROUND

1. Field

Embodiments relate to a semiconductor package including stacked semiconductor chips and a method of fabricating the same.

2. Description of Related Art

A semiconductor package may include a printed circuit board and semiconductor chips stacked on the printed circuit board. However, as more semiconductor chips are stacked, wires to couple the printed circuit board to the semiconductor are longer, increasing costs, parasitic effects, or the like.

### SUMMARY

An embodiment includes a semiconductor package including a circuit board including a plurality of pads; a support structure disposed on the circuit board; and a plurality of semiconductor chips stacked on the circuit board and the support structure, each semiconductor chip including at least one pad. For each semiconductor chip, the at least one pad is aligned with a corresponding pad of the circuit board; and an electrical connection is formed between the at least one pad and the corresponding pad of the circuit board through the support structure.

An embodiment includes a semiconductor package including a circuit board including a plurality of pads; a support structure disposed on the circuit board; and a plurality of first semiconductor chips stacked on the circuit board and the support structure, each first semiconductor chip including at least one pad. For each first semiconductor chip, the at least one pad faces a corresponding pad of the circuit board; and an electrical connection is formed between the at least one pad and the corresponding pad of the circuit board using the support structure.

An embodiment includes a method including attaching a support structure to a circuit board including a plurality of pads; attaching a first semiconductor chip to the circuit board such that a pad of the first semiconductor chip is aligned with a corresponding pad of the circuit board; and attaching a plurality of second semiconductor chips, each second semiconductor chip attached offset from an adjacent first or second semiconductor chip such that a pad of the second semiconductor chip aligns with a corresponding pad of the circuit board through the support structure.

An embodiment includes a semiconductor package including a circuit board including a first pad and a second pad located on a first surface thereof; a first semiconductor chip mounted on the first surface of the circuit board and including a third pad facing the first pad; a second semiconductor chip being stacked offset on the first semiconductor chip and including a fourth pad aligned with the second pad; and a support structure located between the second pad and the fourth pad. The support structure includes a fifth pad facing the second pad, a sixth pad facing the fourth pad, an insulating body located between the fifth pad and the sixth pad, and a conductive pillar penetrating the insulating body to electrically connect the fifth pad and the sixth pad.

An embodiment includes a semiconductor package including a circuit board including a plurality of first pads located on a top surface thereof; semiconductor chips stacked in a terraced configuration on the top surface of the circuit board, and including a plurality of second pads located on bottom surfaces of the semiconductor chips and vertically aligned with the first pads, respectively; a support structure including conductive pillars located between the first pads and the second pads of the semiconductor chips, and an insulating body surrounding the conductive pillars; and a molding element covering the semiconductor chips and the support structure. Each of the second pads of the semiconductor chips is electrically connected to a corresponding first pad by one of the conductive pillars.

Other embodiments will be described in more detail in the specification and drawings.

### BRIEF DESCRIPTION OF THE DRAWINGS

Embodiments are illustrated in the accompanying drawings in which like reference characters refer to the same parts throughout the different views. The drawings are not necessarily to scale, emphasis instead being placed upon illustrating the principles. In the drawings:

FIG. 1A is a cross-sectional view showing a semiconductor package according to an embodiment.

FIG. 1B is a partially enlarged view showing ‘K’ region of FIG. 1A.

FIG. 2 is a cross-sectional view showing a semiconductor package according to another embodiment.

FIG. 3 is a cross-sectional view showing a semiconductor package according to still another embodiment.

FIG. 4 is a cross-sectional view showing a semiconductor package according to yet another embodiment.

FIG. 5 is a cross-sectional view showing a semiconductor package according to yet another embodiment.

FIG. 6 is a cross-sectional view showing a semiconductor package according to yet another embodiment.

FIG. 7 is a cross-sectional view showing a semiconductor package according to yet another embodiment.

FIG. 8 is a cross-sectional view showing a semiconductor package according to yet another embodiment.

FIG. 9 is a cross-sectional view showing a semiconductor package according to yet another embodiment.

FIG. 10 is a cross-sectional view showing a semiconductor package according to yet another embodiment.

FIG. 11 is a cross-sectional view showing a semiconductor package according to yet another embodiment.

FIG. 12A is a plan view showing a semiconductor package according to yet another embodiment.

FIG. 12B is a cross-sectional view taken along lines I-I′ and II-II′ of FIG. 12A.

FIGS. 13A to 13F are cross-sectional views sequentially illustrating a method of fabricating a semiconductor package according to an embodiment.

FIGS. 14A to 14C are cross-sectional views sequentially illustrating a method of fabricating a semiconductor package according to another embodiment.

FIG. 15 is a schematic view showing a semiconductor module including a semiconductor package according to an embodiment.

FIG. 16 is a block diagram showing an electronic device including a semiconductor package according to an embodiment.

FIG. 17 is a perspective view showing a mobile device including a semiconductor package according to an embodiment.

FIG. 18 is a block diagram showing an electronic system including a semiconductor package according to an embodiment.

### DETAILED DESCRIPTION

Embodiments will now be described more fully with reference to the accompanying drawings in which some embodiments are shown. However, specific structural and functional details disclosed herein are merely representative for purposes of describing embodiments. Thus, other embodiments may take many alternate forms and should not be construed as limited to only embodiments set forth herein. Therefore, it should be understood that there is no intent to limit embodiments to the particular forms disclosed, but on the contrary, embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of embodiments. As used herein, the term “and/or” includes any and all combinations of one or more of the associated listed items.

It will be understood that, if an element is referred to as being “connected” or “coupled” with another element, it can be directly connected, or coupled, to the other element or intervening elements may be present. In contrast, if an element is referred to as being “directly connected” or “directly coupled” with another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Embodiments may be described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, embodiments should not be construed as limited to the particular shape illustrated herein but may include deviations in shapes that result, for example, from manufacturing. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe embodiments, various aspects will be described in detail with reference to the attached drawings. However, the present invention is not limited to embodiments described.

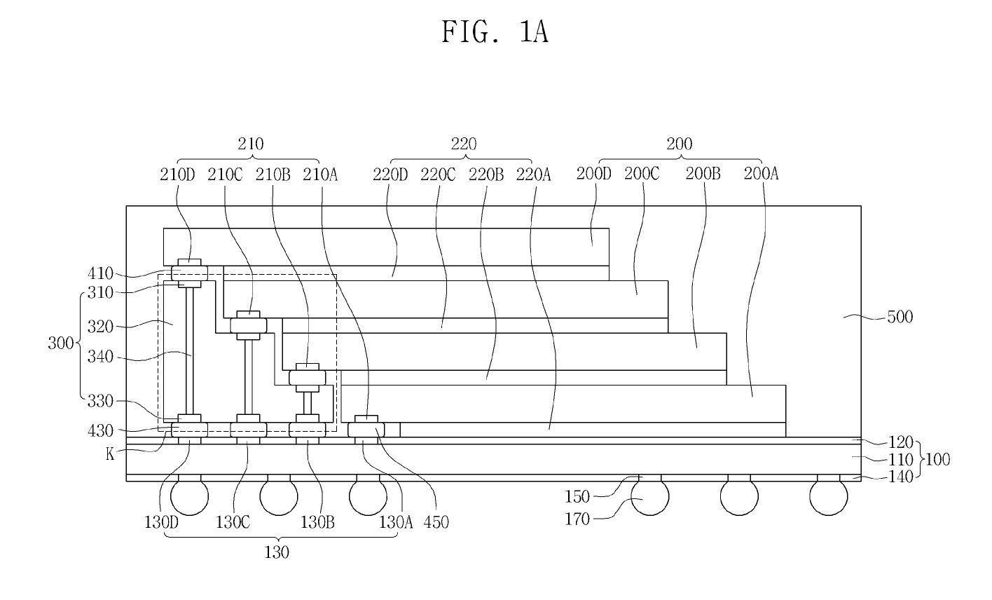

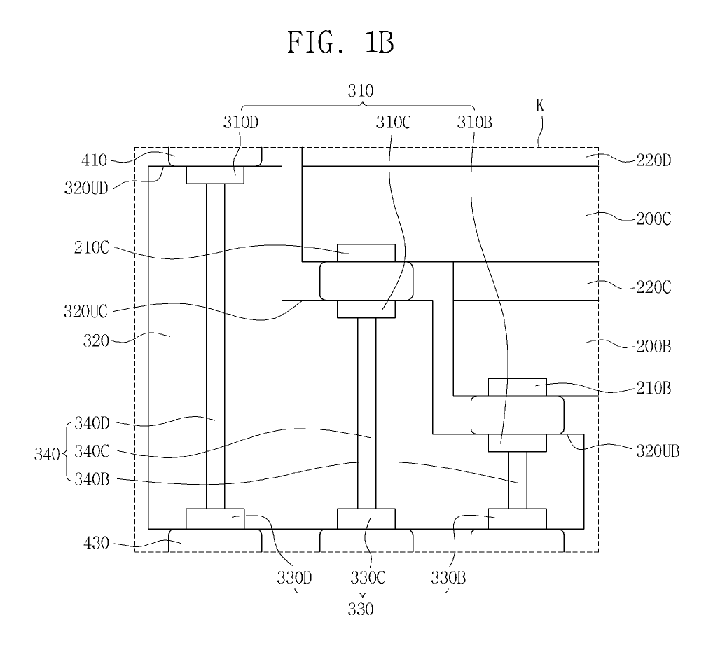

FIG. 1A is a cross-sectional view showing a semiconductor package according to an embodiment, and FIG. 1B is a partially enlarged view showing ‘K’ region of FIG. 1A.

Referring to FIGS. 1A and 1B, a semiconductor package according to an embodiment may include a circuit board 100, semiconductor chips 200 stacked on the circuit board 100, a support structure 300 between an upper surface of the circuit board 100 and exposed lower surfaces of the semiconductor chips 200, and a molding element 500 to cover the semiconductor chips 200 and the support structure 300.

The semiconductor chips 200 may include a first semiconductor chip 200A, a second semiconductor chip 200B, a third semiconductor chip 200C and a fourth semiconductor chip 200D. The first semiconductor chip 200A may be mounted on the circuit board 100. The second semiconductor chip 200B may be stacked offset on the first semiconductor chip 200A. The third semiconductor chip 200C and the fourth semiconductor chip 200D may be sequentially stacked offset on the second semiconductor chip 200B. Although the semiconductor chips 200 have been illustrated as having substantially the same shape, the semiconductor chips 200 can have different shapes, dimensions, or the like. Thus, the semiconductor chips 200 may or may not have a complementary offset orientation on a side opposite the support structure 300 as illustrated in FIG. 1A.

In this embodiment, the semiconductor package includes four semiconductor chips 200A, 200B, 200C and 200D sequentially stacked on the circuit board 100. However, in other embodiments, the semiconductor package may include at least two semiconductor chips stacked on the circuit board 100. For example, the semiconductor package according to the embodiment may disclose semiconductor chips configured in a square number of two, such as two, four, eight, sixteen, thirty two, etc. In another example, the number of semiconductor chips 200 can be any number greater than one.

The circuit board 100 may be a printed circuit board (PCB), a lead frame (LF), a tape interconnection, or the like. The circuit board 100 may be a rigid PCB, a flexible PCB, a rigid and flexible PCB, or the like.

The circuit board 100 may include a board body 110, an upper insulating layer 120, signal pads 130, a lower insulating layer 140, and terminal pads 150. The circuit board 100 may further include external terminals 170 located respectively on the terminal pads 150. Although the external terminals 170 have been illustrated as balls, the external terminals 170 can take any form appropriate to the circuit board 100.

The board body 110 may include one or more signal interconnections electrically connecting the signal pads 130 and the terminal pads 150. The board body 110 may also include a plurality of signal interconnection layers, insulating layers, or the like.

The upper insulating layer 120 may prevent the board body 110 and the semiconductor chips 200 from accidentally being connected. The upper insulating layer 120 may be located on an upper surface of the board body 110. The upper insulating layer 120 may cover the upper surface of the board body 110. The upper insulating layer 120 may include solder resist.

The signal pads 130 may be connected to the semiconductor chips 200, respectively. Each of the signal pads 130 may transmit separate signals to the corresponding one of the semiconductor chips 200. For example, each of the signal pads 130 may transmit an address signal, a data signal, and a command signal to the corresponding one of the semiconductor chips 200. Each of the semiconductor chips 200 may receive or output an independent signal through the corresponding one of the signal pads 130. For convenience of illustration, the signal pads 130 may be referred to as a first signal pad 130A, a second signal pad 130B, a third signal pad 130C and a fourth signal pad 130D, depending on the electrical connection relationship with the semiconductor chips 200. For example, the first signal pad 130A may be electrically connected to the first semiconductor chip 200A. The second signal pad 130B may be electrically connected to the second semiconductor chip 200B. The third signal pad 130C may be electrically connected to the third semiconductor chip 200C. The fourth signal pad 130D may be electrically connected to the fourth semiconductor chip 200D.

The signal pads 130 may be located on the upper surface of the board body 110. The signal pads 130 may be located in the upper surface of the circuit board 100. The signal pads 130 may be defined by the upper insulating layer 120. Upper levels of the signal pads 130 may be the same as an upper level of the upper insulating layer 120. The upper levels of the signal pads 130 may be the same as an upper level of the circuit board 100. The signal pads 130 may include conductive material. For example, the signal pads 130 may include gold (Au), silver (Ag), copper (Cu), nickel (Ni), aluminum (Al), a combination of such materials, or the like.

The lower insulating layer 140 may prevent the board body 110 and the external terminals 170 from accidentally being connected. The lower insulating layer 140 may be located on a lower surface of the board body 110. The lower insulating layer 140 may cover the lower surface of the board body 110. The lower insulating layer 140 may include the same material as the upper insulating layer 120. For example, the lower insulating layer 140 may include solder resist.

The terminal pads 150 may be electrically connected to the external terminals 170. The terminal pads 150 may be located on the lower surface of the board body 110. The terminal pads 150 may be located in a lower surface of the circuit board 100. The terminal pads 150 may be defined by the lower insulating layer 140.

The external terminals 170 may contact the terminal pads 150. The external terminals 170 may include a solder ball, a solder bump, a grid array, a conductive tab, or the like.

The semiconductor chips 200 may be stacked in a terraced configuration on the upper surface of the circuit board 100. The semiconductor chips 200 stacked on the upper surface of the circuit board 100 may be a cascade shape. A portion of a lower surface of the first semiconductor chip 200A may be exposed. A portion of a lower surface of the second semiconductor chip 200B may be exposed by the first semiconductor chip 200A. A portion of a lower surface of the third semiconductor chip 200C may be exposed by the second semiconductor chip 200B. A portion of a lower surface of the fourth semiconductor chip 200D may be exposed by the third semiconductor chip 200C.

The semiconductor chips 200 may include a dynamic random access memory (DRAM) chip, a flash memory chip, a variable resistance memory chip, a combination of such chips, or the like. The semiconductor chips 200 may be substantially the same chip. Accordingly, horizontal widths of the semiconductor chips 200 may be substantially the same.

The semiconductor chips 200 may include input/output pads 210 located in lower surfaces thereof. For convenience of illustration, the input/output pads 210 may be referred to as a first input/output pad 210A, a second input/output pad 210B, a third input/output pad 210C, and a fourth input/output pad 210D, depending on the positional relationship with the semiconductor chips 200. For example, the first input/output pad 210A may be located in a lower surface of the first semiconductor chip 200A. The second input/output pad 210B may be located in the lower surface of the second semiconductor chip 200B. The third input/output pad 210C may be located in the lower surface of the third semiconductor chip 200C. The fourth input/output pad 210D may be located in the lower surface of the fourth semiconductor chip 200D.

Second to fourth input/output pads 210B to 210D may be located in exposed lower surfaces of second to fourth semiconductor chips 200B to 200D. For example, the second input/output pad 210B may be located in an exposed lower surface of the second semiconductor chip 200B. The third input/output pad 210C may be located in an exposed lower surface of the third semiconductor chip 200C. The fourth input/output pad 210D may be located in an exposed lower surface of the fourth semiconductor chip 200B.

The input/output pads 210 may be located in substantially the same regions of the semiconductor chips 200. For example, a horizontal distance between a left side surface of the first semiconductor chip 200A and a left side surface of the first input/output pad 210A may be substantially the same as a horizontal distance between a left side surface of the second semiconductor chip 200B and a left side surface of the second input/output pad 210B.

Levels of lower surfaces of the input/output pads 210 may be substantially the same as levels of the lower surfaces of the semiconductor chips 200. For example, a level of a lower surface of the first input/output pad 210A may be substantially the same as a level of the lower surface of the first semiconductor chip 200A.

The input/output pads 210 may be electrically connected to the signal pads 130, respectively. For example, the first input/output pad 210A may be electrically connected to the first signal pad 130A. The second input/output pad 210B may be electrically connected to the second signal pad 130B. The third input/output pad 210C may be electrically connected to the third signal pad 130C. The fourth input/output pad 210D may be electrically connected to the fourth signal pad 130D.

The input/output pads 210 may be aligned (e.g., vertically aligned) with the signal pads 130, respectively. For example, the first input/output pad 210A may be aligned (e.g., vertically aligned) with the first signal pad 130A. The second input/output pad 210B may be aligned (e.g., vertically aligned) with the second signal pad 130B. The third input/output pad 210C may be aligned (e.g., vertically aligned) with the third signal pad 130C. The fourth input/output pad 210D may be aligned (e.g., vertically aligned) with the fourth signal pad 130D. The first input/output pad 210A may face the first signal pad 130A.

In an embodiment, the signal pads 130 may be located within a region of the circuit board 100 vertically overlapping the semiconductor chips 200. As a result, in an embodiment, as compared with the existing semiconductor packages, an available area of the circuit board 100 for stacking the semiconductor chips 200 may be increased, a size of the circuit board 100 can be reduced, or the like.

The input/output pads 210 may include conductive material. For example, the input/output pads 210 may include gold (Au), silver (Ag), copper (Cu), nickel (Ni), aluminum (Al), a combination of such materials, or the like. The input/output pads 210 may include substantially the same material as the signal pads 130.

In an embodiment, the semiconductor package may further include adhesive layers 220 located respectively on the lower surfaces of the semiconductor chips 200. For convenience of illustration, the adhesive layers 220 may be referred to as a first adhesive layer 220A, a second adhesive layer 220B, a third adhesive layer 220C and a fourth adhesive layer 220D, depending on the positional relationship with the semiconductor chips 200. For example, the first adhesive layer 220A may be located on the lower surface of the first semiconductor chip 200A. The second adhesive layer 220B may be located on the lower surface of the second semiconductor chip 200B. The third adhesive layer 220C may be located on the lower surface of the third semiconductor chip 200C. The fourth adhesive layer 220D may be located on the lower surface of the fourth semiconductor chip 200D. The first adhesive layer 220A may be located between the circuit board 100 and the first semiconductor chip 200A. The second adhesive layer 220B may be located between the first semiconductor chip 200A and the second semiconductor chip 200B. The third adhesive layer 220C may be located between the second semiconductor chip 200B and the third semiconductor chip 200C. The fourth adhesive layer 220D may be located between the third semiconductor chip 200C and the fourth semiconductor chip 200D.

The adhesive layers 220 may be separated from the input/output pads 210. For example, the first adhesive layer 220A may be separated from the first input/output pad 210A. The second to fourth adhesive layers 220B to 220D may not cover the exposed lower surfaces of the second to fourth semiconductor chips 200B to 200D. For example, the second adhesive layer 220B may not cover the exposed lower surface of the second semiconductor chip 200B from the first semiconductor chip 200A.

The adhesive layers 220 may have substantially the same thickness. For example, a thickness of the first adhesive layer 220A may be substantially the same as a thickness of the second adhesive layer 220B. A vertical distance between a level of the upper surface of the circuit board 100 and a level of the lower surface of the first semiconductor chip 200A may be substantially the same as a vertical distance between a level of the upper surface of the semiconductor chip 200A and a level of the lower surface of the second semiconductor chip 200B.

The support structure 300 may support the exposed lower surfaces in the semiconductor chips 200. That is, the support structure 300 may be located between the circuit board 100 and the exposed lower surfaces of the second to fourth semiconductor chips 200B to 200D. The support structure 300 may include upper pads 310, an insulating body 320, lower pads 330, and conductive pillars 340.

The upper pads 310 may be electrically connected to the second to fourth input/output pads 210B to 210D, respectively. For convenience of illustration, the upper pads 310 may be referred to as a first upper pad 310B, a second upper pad 310C, and a third upper pad 310D, depending on the electrical connection relationship with the input/output pads 210. For example, the first upper pad 310B may be electrically connected to the second input/output pad 210B. The second upper pad 310C may be electrically connected to the third input/output pad 210C. The third upper pad 310D may be electrically connected to the fourth input/output pad 210D.

The upper pads 310 may be aligned (e.g., vertically aligned) with the input/output pads 210, such that an upper pad 310 horizontally overlaps with a corresponding input/output pad 210. For example, the first upper pad 310B may be aligned (e.g., vertically aligned) with the second input/output pad 210B. The second upper pad 310C may be aligned (e.g., vertically aligned) with the third input/output pad 210C. The third upper pad 310D may be aligned (e.g., vertically aligned) with the fourth input/output pad 210D. The upper pads 310 may face the input/output pads 210, respectively. For example, the first upper pad 310B may face the second input/output pad 210B. The second upper pad 310C may face the third input/output pad 210C. The third upper pad 310D may face the fourth input/output pad 210D.

Vertical distances between the upper pads 310 and the input/output pads 210 may be substantially the same. For example, a vertical distance between the first upper pad 310B and the second input/output pad 210B may be substantially the same as a vertical distance between the second upper pad 310C and the third input/output pad 210C. Each of the vertical distances between the upper pads 310 and the input/output pads 210 may be substantially the same as a thickness of each of the adhesive layers 220. In another embodiment, the vertical distances between the upper pads 310 and the input/output pads 210 may be different from a thickness of each of the adhesive layers 220. For example, a height of an upper surface of semiconductor chip 200B may be higher or lower than an upper surface of the second upper pad 310C. A thickness of the adhesive layer 220C or other intervening layers, structures, or the like may accommodate such a difference.

The upper pads 310 may include a conductive material. For example, the upper pads 310 may include gold (Au), silver (Ag), copper (Cu), nickel (Ni), aluminum (Al), or the like. The upper pads 310 may include substantially the same material as the input/output pads 210.

The insulating body 320 may support the exposed lower surfaces of the second to fourth semiconductor chips 200. The insulating body 320 may be located between the upper pads 310 and the lower pads 330. The insulating body 320 may be located between the circuit board 100 and the exposed lower surfaces of the second to fourth semiconductor chips 200B to 200D. The insulating body 320 may be located between second to fourth signal pads 130B to 130D, and the second to fourth input/output pads 210B to 210D.

An upper surface of the insulating body 320 may have a cascade or terraced shape including step surfaces 320UB to 320UD, which face the exposed lower surfaces of the second to fourth semiconductor chips 200B to 200D, respectively. For convenience of illustration, the step surfaces 320UB to 320UD may be referred to as a first step surface 320UB, a second step surface 320UC, and a third step surface 320UD, depending on the positional relationship with the first to fourth semiconductor chips 200A to 200D. For example, the first step surface 320UB may be considered as one portion of the upper surface of the insulating body 320, which vertically faces the exposed lower surface of the second semiconductor chip 200B. The second step surface 320UC may be considered as another portion of the upper surface of the insulating body 320, which vertically faces the exposed lower surface of the third semiconductor chip 200C. The third step surface 320UD may be considered as the other remaining portion of the upper surface of the insulating body 320, which vertically faces the exposed lower surface of the fourth semiconductor chip 200D. The upper surface of the insulating body 320 may be parallel to the exposed lower surfaces of the semiconductor chips 200. In addition, the upper surface of the insulating body 320 may be substantially parallel to left side surfaces of the semiconductor chips 200.

Each of the step surfaces 320UB to 320UD may include the corresponding one of the upper pads 310 of the insulating body 320. For example, the first upper pad 310B of the insulating body 320 is disposed at the first step surface 320UB. Each of upper surfaces of the step surfaces 320UB to 320UD may be substantially the same level as upper surfaces of corresponding one of the upper pads 310. For example, an upper surface of the first step surface 320UB may be substantially the same level as an upper surface of the first upper pad 310B. The insulating body 320 may surround side surfaces and lower surfaces of the upper pads 310. The upper pads 310 are isolated from each other by the insulating body 320.

Vertical distances between each of the step surfaces 320UB to 320UD of the insulating body 320, and the corresponding one of the exposed lower surfaces of the second to fourth semiconductor chips 200B to 200D may be substantially the same. For example, a vertical distance between the first step surface 320UB and the exposed lower surface of the second semiconductor chip 200B may be substantially the same as a vertical distance between the second step surface 320UC and the exposed lower surface of the third semiconductor chip 200C.

Each height difference between the step surfaces 320UB to 320UD of the insulating body 320 may be substantially the same in size as a sum of a thickness of the corresponding one of the semiconductor chips 200 and a thickness of the corresponding one of the adhesive layers 220 and any other intervening layers, structures, or the like. For example, a height difference between the first step surface 320UB and the second step surface 320UC may be substantially the same in size as a sum of a thickness of the second semiconductor chip 200B and a thickness of the second adhesive layer 220B. The height difference between particular step surfaces 320UB to 320UD of the insulating body 320 may, but need not be equal.

Each of the step surfaces 320UB to 320UD of the insulating body 320 may be substantially the same level as the corresponding one of lower surfaces of the adhesive layers 220 under the corresponding one of the semiconductor chips 200. For example, the first step surface 320UB may be substantially the same level as a lower surface of the second adhesive layer 220B. Each of upper surfaces of the step surfaces 320UB to 320UD may be substantially the same level as an upper surface of a neighboring semiconductor chip 200 under the corresponding one of the semiconductor chips 200. For example, the first step surface 320UB may be substantially the same level as the first semiconductor chip 200A under the second semiconductor chip 200B.

A lower surface of the insulating body 320 may be parallel to the upper surface of the circuit board 100. A vertical distance between the upper surface of the circuit board 100 and the lower surface of the insulating body 320 may be substantially the same as a vertical distance between the upper surface of the circuit board 100 and the lower surface of the semiconductor chip 200A. The vertical distance between the upper surface of the circuit board 100 and the lower surface of the insulating body 320 may be substantially the same as a thickness of each of the adhesive layers 220.

The insulating body 320 may include insulating material. For example, the insulating body 320 may include thermosetting resin. The insulating body 320 may include substantially the same material as the molding element 500. The insulating body 320 may harden more than the molding element 500.

The lower pads 330 may be electrically connected to the second to fourth signal pads 130B to 130D, respectively. For convenience of illustration, the lower pads 330 may be referred to as a first lower pad 330B, a second lower pad 330C, and a third lower pad 330D, depending on the positional relationship with the second to fourth signal pads 130B to 130D. For example, the first lower pad 330B may be electrically connected to the second signal pad 130B. The second lower pad 330C may be electrically connected to the third signal pad 130C. The third lower pad 330D may be electrically connected to the fourth signal pad 130D.

The lower pads 330 may be aligned (e.g., vertically aligned) with the second to fourth signal pads 130B to 130D such that a lower pad 330 horizontally overlaps a corresponding signal pad 130. For example, the first lower pad 330B may be aligned (e.g., vertically aligned) with the second signal pad 130B. The second lower pad 330C may be aligned (e.g., vertically aligned) with the third signal pad 130C. The third lower pad 330D may be aligned (e.g., vertically aligned) with the fourth signal pad 130D. The lower pads 330 may face the second to fourth signal pads 130B to 130D, respectively. For example, the first lower pad 330B may face the second signal pad 130B. The second lower pad 330C may face the third signal pad 130C. The third lower pad 330D may face the fourth signal pad 130D.

The lower pads 330 may include conductive material. For example, the lower pads 330 may include substantially the same material as the upper pads 310. The lower pads 330 may include substantially the same material as the signal pads 130. However, the signal pads 130, upper pads 310, and lower pads 330 can include different materials.

The conductive pillars 340 may electrically connect the upper pads 310 to the lower pads 330. The conductive pillars 340 may be referred to as a first conductive pillar 340B, a second conductive pillar 340C, and a third conductive pillar 340D, depending on the positional relationship with the second to fourth signal pads 130B to 130D. For example, the first conductive pillar 340B may electrically connect the first upper pad 310B to the first lower pad 330B. The second conductive pillar 340C may electrically connect the second upper pad 310C to the second lower pad 330C. The third conductive pillar 340D may electrically connect the third upper pad 310D to the third lower pad 330D.

The conductive pillars 340 may be in direct contact with the upper pads 310 and the lower pads 330. For example, the first conductive pillar 340B may be in direct contact with a lower surface of the first upper pad 310B and an upper surface of the first lower pad 330B. The second conductive pillar 340C may be in direct contact with a lower surface of the second upper pad 310C and an upper surface of the second lower pad 330C. The third conductive pillar 340D may be in direct contact with a lower surface of the third upper pad 310D and an upper surface of the third lower pad 330D.

The conductive pillars 340 may penetrate the insulating body 320. The conductive pillars 340 may be insulated from each other by the insulating body 320. The conductive pillars 340 may respectively correspond to the step surfaces 320UB to 320UD to be in the insulating body 320. For example, the first conductive pillar 340B may correspond to the first step surface 320UB to be in the insulating body 320.

Each of the conductive pillars 340 may penetrate the insulating body 320 under the corresponding one of the step surfaces 320UB to 320UD. For example, the first conductive pillar 340B may penetrate the insulating body 320 under the first step surface 320UB. The second conductive pillar 340C may penetrate the insulating body 320 under the second step surface 320UC. The third conductive pillar 340D may penetrate the insulating body 320 under the third step surface 320UD.

The conductive pillars 340 may have different vertical heights. For example, a vertical height of the second conductive pillar 340C may be higher than that of the first conductive pillars 340B, and may be smaller than that of the third conductive pillar 340D. A vertical height difference between any two neighboring conductive pillars 340 may be substantially the same in size as a height difference between the corresponding two of the step surfaces 320UB to 320UD. For example, a vertical height difference between the first conductive pillar 340B and the second conductive pillar 340C may be substantially the same in size as a height difference between the first step surface 320UB and the second step surface 320UC.

The conductive pillars 340 may include conductive material. For example, the conductive pillars 340 may include gold (Au), silver (Ag), copper (Cu), nickel (Ni), aluminum (Al), or the like. The conductive pillars 340 may include substantially the same material as the upper pads 310. The conductive pillars 340 may include substantially the same material as the lower pads 330. However, the conductive pillars 340, upper pads 310, and lower pads 330 may include different materials.

In an embodiment, the input/output pads 210 of the semiconductor chips 200 may be electrically connected to the signal pads 130, respectively, through the upper pads 310, the lower pads 330 and the conductive pillars 340 in the support structure 300. As such, in the semiconductor package, the semiconductor chips 200 may be stacked and bonded using flip chip techniques regardless of the locations of the stacked semiconductor chips 200. That is, in an embodiment, a stacking process of the semiconductor chips 200 may be simplified. As a result, in an embodiment, process time and/or materials required in the stacking process of the semiconductor chips 200 may be reduced.

In an embodiment, the upper pads 310, the lower pads 330 and the conductive pillars 340 may be surrounded by the insulating body 320. That is, an electrical connection between the input/output pads 210 of the semiconductor chips 200 and the signal pads 130 of the circuit board 100 may be protected by the insulating body 320. As such, the input/output pads 210 and the signal pads 130 may be stably connected between the semiconductor chips 200 and the circuit board 100. That is, reliability of electrical connection of the semiconductor chips 200 may be improved.

In an embodiment, the semiconductor package may further include first connection elements 410 located between the second to fourth input/output pads 210B to 210D and the upper pads 310, second connection elements 430 located between second to fourth signal pads 130B to 130D and the upper pads 330, and a third connection element 450 located between the first signal pad 130A and the first input/output pad 210A.

The first connection elements 410 may electrically connect the second to fourth input/output pads 210B to 210D to corresponding upper pads 310. For example, the second input/output pad 210B may be electrically connected to the first upper pad 310B through one of the first connection elements 410. The first connection elements 410 may be in direct contact with the second to fourth input/output pads 210B to 210D and the upper pads 310. For example, the one of the first connection elements 410 may be in direct contact with the second input/output pad 210B and the first upper pad 310B.

The first connection elements 410 may be located on the step surfaces 320UB to 320UD of the insulating body 320, respectively. For example, the one of the first connection elements 410, which is electrically connected to the second input/output pad 210B and the first upper pad 310B, may be located on the first step surface 320UB. The first connection elements 410 may be in direct contact with the exposed lower surfaces of the second to fourth semiconductor chips 200B to 200D, and the step surfaces 320UB to 320UD. For example, the one of the first connection elements 410, which is electrically connected to the second input/output pad 210B and the first upper pad 310B, may be in direct contact with the exposed lower surface of the second semiconductor chip 200B and the first step surface 320UB. The first connection elements 410 may include a solder ball.

The second connection elements 430 may electrically connect the second to fourth signal pads 130B to 130D to corresponding lower pads 330. For example, the second signal pad 130B may be electrically connected to the first lower pad 330B through one of the second connection elements 430. The second connection elements 430 may be in direct contact with the second to fourth signal pads 130B to 130D and the lower pads 330. For example, the one of the second connection elements 430 may be in direct contact with the second signal pad 130B and the first lower pad 330B.

The second connection elements 430 may be separated from each other. The one of the second connection elements 430, which is electrically connected to the second signal pad 130B and the first lower pad 330B, may be separated from another of the second connection elements 430, which is electrically connected to the third signal pad 130C and the second lower pad 330C. The second connection elements 430 may be in direct contact with the upper surface of the circuit board 100 and the lower surface of the insulating body 320.

The second connection elements 430 may include substantially the same material as the first connection elements 410. For example, the second connection elements 430 may include a solder ball. However, in another embodiment, the first connection elements 410 and second connection elements 430 may include different materials.

In the semiconductor package according to the embodiment, the first connection elements 410 may allow the exposed lower surfaces of the semiconductor chips 200 to be physically supported by the support structure 300. Also, in the semiconductor package according to the embodiment, the second connection elements 430 may allow the support structure 300 to be physically supported by the circuit board 100. As such, in the semiconductor package according to the embodiment, load applied to the exposed lower surfaces of the second to fourth semiconductor chips 200B to 200D, which are stacked in a terraced configuration, may be dispersed. That is, in the semiconductor package according to the embodiment, structural stability of the second to fourth semiconductor chips 200B to 200D may be maintained due to the support structure 300. As a result, in an embodiment, any deterioration of structural stability of the semiconductor package due to a number of stacked semiconductor chips may be reduced.

The third connection element 450 may electrically connect the first signal pad 130A and the first input/output pad 210A. The third connection element 450 may be in direct contact with the first signal pad 130A and the first input/output pad 210A. The third connection element 450 may be in direct contact with the upper surface of the circuit board 100 and the lower surface of the first semiconductor chip 200A.

A thickness of the third connection element 450 may be substantially the same as a thickness of each of the second connection element 430. The thickness of the third connection element 450 may be substantially the same as a thickness of each of the adhesive layers 220. The thickness of the third connection element 450 may be substantially the same as a thickness of each of the first connection elements 410.

The third connection element 450 may include substantially the same material as the first connection elements 410. For example, the third connection element 450 may include a solder ball. However, in another embodiment, the first connection elements 410 and the third connection element 450 may include different materials.

The molding element 500 may cover the semiconductor chips 200 and the support structure 300. The molding element 500 may surround the first connection elements 410, the second connection elements 430, and the third connection element 450. The molding element 500 may fill spaces between the circuit board 100 and the semiconductor chips 200, between the semiconductor chips 200 and the support structure 300, and between the circuit board 100 and the support structure 300.

The molding element 500 may include thermosetting resin. For example, the molding element 500 may include epoxy molding compound (EMC). The molding element 500 may include material having high fluidity. For example, the molding element 500 may include material used in a MUF (Molded Underfill for Flip chip) process.

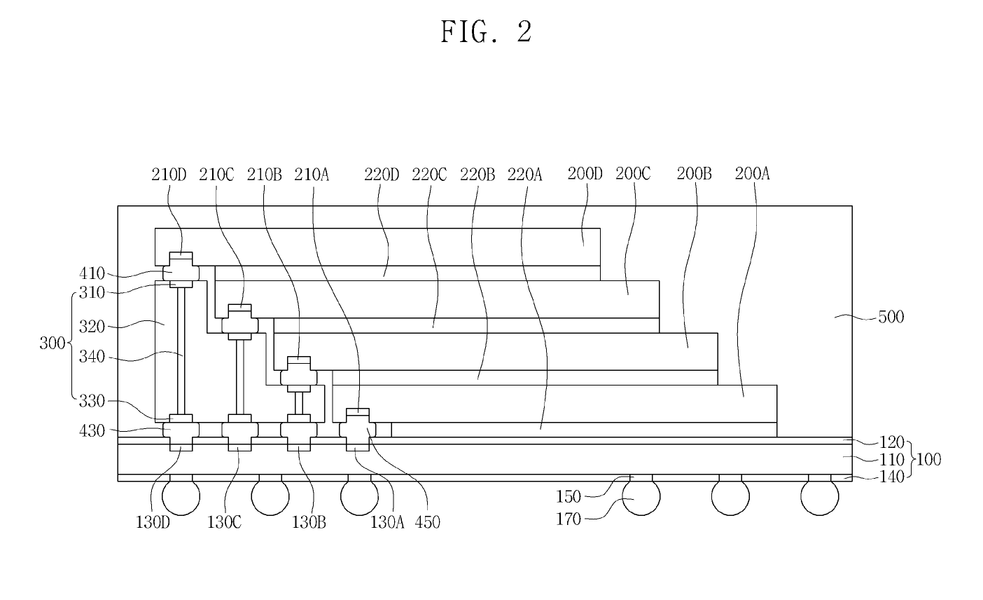

FIG. 2 is a cross-sectional view showing a semiconductor package according to another embodiment. Referring to FIG. 2, a semiconductor package according to another embodiment may include a circuit board 100 including first to fourth signal pads 130A to 130D, first to fourth semiconductor chips 200A to 200D stacked offset on the circuit board 100, a support structure 300 located between the circuit board 100 and the second to fourth semiconductor chips 200B to 200D, first connection elements 410 located between exposed lower surfaces of the first to fourth semiconductor chips 200A to 200D and the support structure 300, second connection elements 430 located between the circuit board 100 and the support structure 300, a third connection element 450 located between a first signal pad 130A and a first input/output pad 210A, and a molding element 500 covering the first to fourth semiconductor chips 200A to 200D and the support structure 300.

A level of an upper surface of the circuit board 100 may be higher than levels of upper surfaces of the first to fourth signal pads 130A to 130D. The levels of the upper surfaces of the first to fourth signal pads 130A to 130D may be lower than a level of an upper surface of an upper insulating layer 120. For example, the levels of the upper surfaces of the first to fourth signal pads 130A to 130D may be substantially the same as a level of an upper surface of a board body 110.

Levels of lower surfaces of the second connection elements 430 may be lower than the level of the upper surface of the upper insulating layer 120. The levels of lower surfaces of the second connection elements 430 may be substantially the same as the levels of the upper surfaces of the first to fourth signal pads 130A to 130D. The second connection elements 430 may extend into openings in the upper insulating layer 120. The second connection elements 430 may contact side surfaces of the upper insulating layer 120 within the corresponding openings.

A level of a lower surface of the third connection element 450 may be lower than the level of the upper surface of the upper insulating layer 120. The level of the lower surface of the third connection element 450 may be substantially the same as a level of an upper surface of a first signal pad 130A. The third connection element 450 may extend into an opening of the upper insulating layer 120. The third connection element 450 may contact side surfaces of the upper insulating layer 120 within the corresponding opening.

Levels of lower surfaces of the first to fourth semiconductor chips 200A to 200D may be lower than those of lower surfaces of first to fourth input/output pads 210A to 210D. For example, a level of a lower surface of a first input/output pad 210A may be higher than a level of a lower surface of a first semiconductor chip 200A.

A level of an upper surface of each of the first connection elements 410 may be higher than that of a lower surface of the corresponding one of second to fourth semiconductor chips 200B to 200D. The level of the upper surface of each of the first connection elements 410 may be substantially the same as a level of a lower surface of the corresponding one of second to fourth input/output pads 210B to 210D. The first connection elements 410 may extend into an inside of the second to fourth semiconductor chips 200B to 200D.

A level of an upper surface of the third connection element 450 may be higher than the level of the lower surface of a first semiconductor chip 200A. The level of the upper surface of the third connection element 450 may be substantially the same as the level of the lower surface of a first input/output pad 210A. The third connection element 450 may extend into the inside of the first semiconductor chip 200A.

A level of a lower surface of an insulating body 320 of the support structure 300 may be substantially the same as levels of lower surfaces of lower pads 330. A thickness of each of the second connection elements 430 may be smaller than a thickness of the third connection element 450.

Each of step surfaces of the insulating body 320 may be substantially the same level as an upper surface of the corresponding one of the upper pads 330. A thickness of each of the first connection elements 410 may be smaller than the thickness of the third connection element 450.

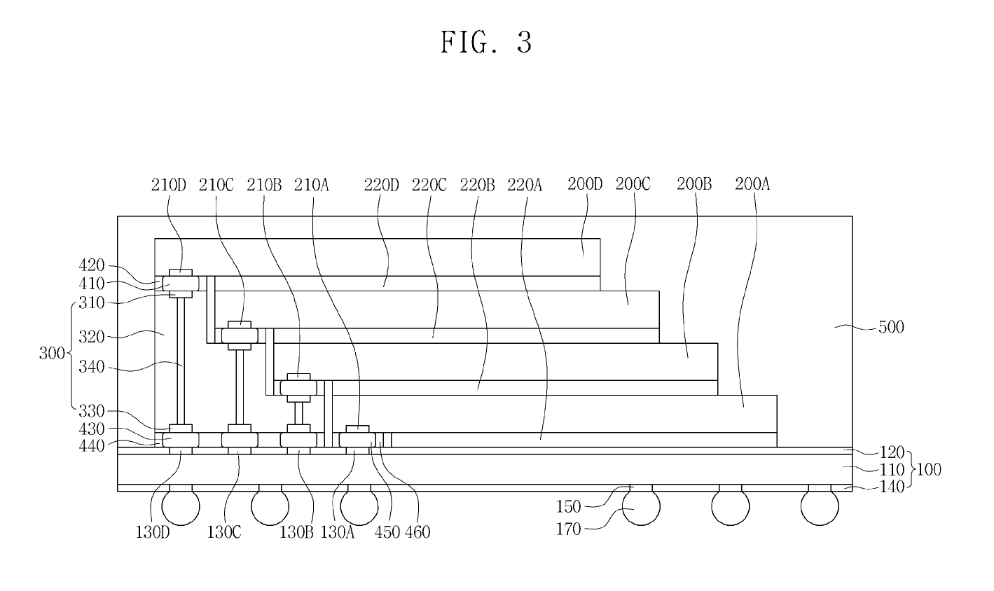

FIG. 3 is a cross-sectional view showing a semiconductor package according to still another embodiment. Referring to FIG. 3, a semiconductor package according to still another embodiment may include a circuit board 100, first to fourth semiconductor chips 200A to 200D, a support structure 300, first connection elements 410, first filling elements 420, second connection elements 430, a second filling element 440, a third connection element 450, a third filling element 460 and a molding element 500.

The first filling elements 420 may surround the first connection elements 410, respectively. The first filling elements 420 may be in direct contact with side surfaces of the first connection elements 410. The first filling elements 420 may fill spaces between exposed lower surfaces of second to fourth semiconductor chips 200B to 200D, and an insulating body 320. The first filling elements 420 may be in direct contact with the exposed lower surfaces of second to fourth semiconductor chips 200B to 200D, and step surfaces of the insulating body 320.

The first filling elements 420 may include insulating material. The first filling elements 420 may include adhesive material. For example, the first filling elements 420 may include a liquid type adhesive, an EMC having high fluidity, a B-stage film type adhesive, or the like.

The second filling element 440 may surround the second connection elements 430. The second filling element 440 may be in direct contact with side surfaces of the second connection elements 430. The second filling element 440 may fill a space between the circuit board 100 and the insulating body 320. The second filling element 440 may be in direct contact with an upper surface of the circuit board 100 and a lower surface of the insulating body 320.

The second filling element 440 may include insulating material. The second filling element 440 may include adhesive material. For example, the second filling element 440 may include substantially the same material as the first filling elements 420. However, in an embodiment, the materials of the first filling elements 420 and second filling elements 440 may be different.

The third filling element 460 may surround the third connection element 450. The third filling element 460 may be in direct contact with side surfaces of the third connection element 450. The third filling element 460 may fill a space between the circuit board 100 and a first semiconductor chip 200A. The third filling element 460 may be in direct contact with the upper surface of the circuit board 100 and the lower surface of the first semiconductor chip 200A. The third filling element 460 may, but need not be separated from a first adhesive layer 220A.

The third filling element 460 may include insulating material. The third filling element 460 may include adhesive material. For example, the third filling element 460 may include substantially the same material as the first filling elements 420. However, in an embodiment, the materials of the first filling elements 420, second filling elements 440, and third filling element 460 may be different.

The molding element 500 may surround the first filling elements 420, the second filling element 440, and the third filling element 460. The molding element 500 may fill spaces between the first filling elements 420. The molding element 500 may fill a space between the second filling element 440 and the third filling element 460. The molding element 500 may fill a space between the first adhesive layer 220A and the third filling element 460. The molding element 500 may fill spaces between side surfaces of the first to fourth semiconductor chips 200A to 200D, and the corresponding side surfaces of the support structure 300 and/or first filling elements 420.

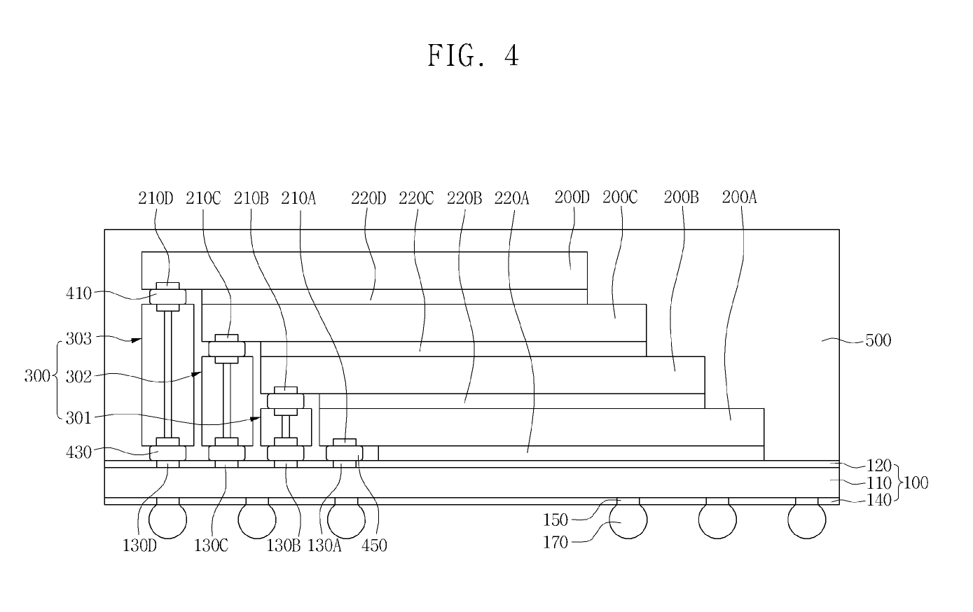

FIG. 4 is a cross-sectional view showing a semiconductor package according to yet another embodiment. Referring to FIG. 4, in an embodiment, the semiconductor package may include a circuit board 100, first to fourth semiconductor chips 200A to 200D, a support structure 300, first connection elements 410, second connection elements 430, a third connection element 450 and a molding element 500.

The support structure 300 may include a first sub support structure 301, a second sub support structure 302, and a third sub support structure 303. The first sub support structure 301 may be located between a second signal pad 130B and a second input/output pad 210B. The second sub support structure 302 may be located between a third signal pad 130C and a third input/output pad 210C. The third sub support structure 303 may be located between a fourth signal pad 130D and a fourth input/output pad 210D.

A level of a lower surface of the first sub support structure 301 may be substantially the same as a level of a lower surface of a first semiconductor chip 200A. A level of an upper surface of the first sub support structure 301 may be substantially the same as a level of an upper surface of the first semiconductor chip 200A. A vertical height of the first sub support structure 301 may be substantially the same in size as a thickness of the first semiconductor chip 200A.

A left side surface of the first sub support structure 301 may be aligned (e.g., vertically aligned) with a left side surface of a second semiconductor chip 200B. The upper surface of the first sub support structure 301 may face an exposed lower surface of the second semiconductor chip 200B.

A level of a lower surface of the second sub support structure 302 may be substantially the same as the level of the lower surface of the first semiconductor chip 200A. The level of the lower surface of the second sub support structure 302 may be substantially the same as the level of the lower surface of the first sub support structure 301. A level of an upper surface of the second sub support structure 302 may be substantially the same as a level of an upper surface of the second semiconductor chip 200B. A vertical height of the second sub support structure 302 may be higher than the vertical height of the first sub support structure 301.

The second sub support structure 302 may be separated from the first sub support structure 301. For example, a right side surface of the second sub support structure 302 may be separated from the left side surface of the first sub support structure 301. The right side surface of the second sub support structure 302 may be separated from the left side surface of the second semiconductor chip 200B. A left side surface of the second sub support structure 302 may be aligned (e.g., vertically aligned) with a left side surface of a third semiconductor chip 200C. An upper surface of the second sub support structure 302 may face an exposed lower surface of the third semiconductor chip 200C.

A vertical height difference between the first sub support structure 301 and the second sub support structure 302 may substantially the same size as a vertical distance between the level of the upper surface of the first semiconductor chip 200A and the level of the upper surface of the second semiconductor chip 200B. The vertical height difference between the first sub support structure 301 and the second sub support structure 302 may be substantially the same size as a sum of a thickness of the second semiconductor chip 200B, a thickness of a second adhesive layer 220B, and any other intervening layers, structures, or the like, if present.

A level of a lower surface of the third sub support structure 303 may be substantially the same as the level of the lower surface of the first semiconductor chip 200A. The level of the lower surface of the third sub support structure 303 may be substantially the same as the level of the lower surface of the second sub support structure 302. A level of an upper surface of the third sub support structure 303 may be substantially the same as a level of an upper surface of the third semiconductor chip 200C. A vertical height of the third sub support structure 303 may be higher than the vertical height of the second sub support structure 302.

The third sub support structure 303 may be separated from the second sub support structure 302. For example, a right side surface of the third sub support structure 303 may be separated from the left side surface of the second sub support structure 302. The right side surface of the third sub support structure 303 may be separated from the left side surface of the third semiconductor chip 200C. A left side surface of the third sub support structure 303 may be aligned (e.g., vertically aligned) with a left side surface of a fourth semiconductor chip 200D. An upper surface of the third sub support structure 303 may face an exposed lower surface of the fourth semiconductor chip 200D.

A vertical height difference between the second sub support structure 302 and the third sub support structure 303 may be substantially the same in size as a vertical distance between the level of the upper surface of the second semiconductor chip 200B and the level of the upper surface of the third semiconductor chip 200C. The vertical height difference between the second sub support structure 302 and the third sub support structure 303 may be substantially the same size as a sum of a thickness of the third semiconductor chip 200C, a thickness of a third adhesive layer 220C, and any other intervening layers, structures, or the like, if present.

The molding element 500 may fill spaces between the first sub support structure 301 and the second sub support structure 302, and between the second sub support structure 302 and the third sub support structure 303.

Although various sides of sub support structures 301 to 303 have been described as being aligned (e.g., vertically aligned) with sides of corresponding semiconductor chips 200B to 200D, in an embodiment, a shape of the semiconductor chip 200, a position of the input/output pad 210, a width of the sub support structures 301 to 303, or the like can be varied such that the sides are not aligned. Moreover, although the sub support structures 301 to 303 have been described as having upper surfaces that are at substantially the same level as upper surfaces of adjacent semiconductor chips 200A to 200C, due to variations in thickness of the semiconductor chips 200A to 200C, adhesive layers 200A to 200C, first connection elements 410, or the like, the surfaces may not be at substantially the same level.

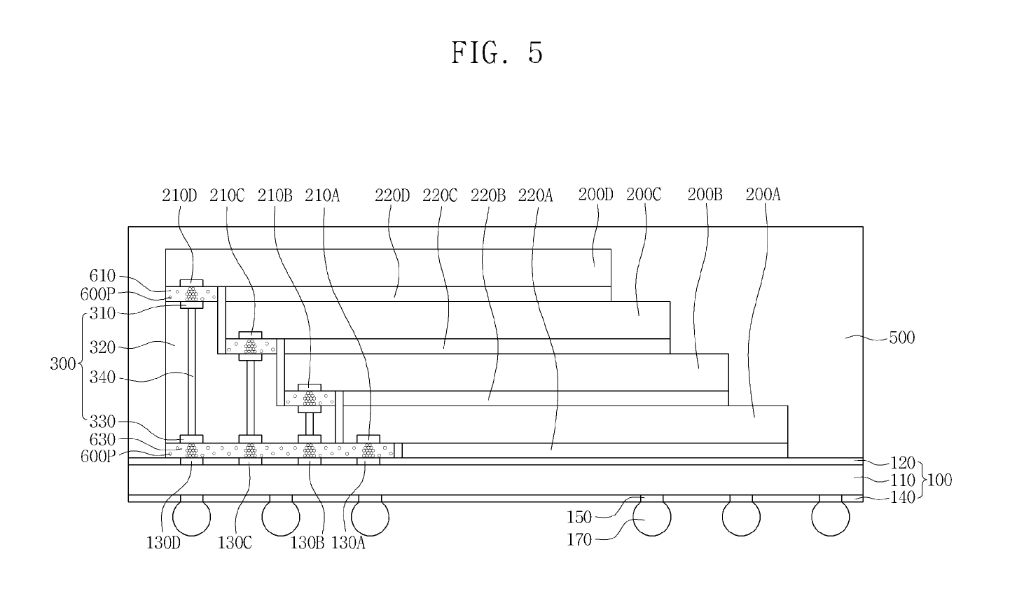

FIG. 5 is a cross-sectional view showing a semiconductor package according to yet another embodiment. Referring to FIG. 5, in an embodiment, a semiconductor package may include a circuit board 100, first to fourth semiconductor chips 200A to 200D, a support structure 300, a molding element 500, first anisotropic conductive elements 610, and a second anisotropic conductive element 630. The first anisotropic conductive elements 610 and the second anisotropic conductive element 630 may include conductive particles 600P.

The first anisotropic conductive elements 610 may fill spaces between exposed lower surfaces of the second to fourth semiconductor chips 200B to 200D and step surfaces of an insulating body 320. The first anisotropic conductive elements 610 may be in direct contact with the exposed lower surfaces of the second to fourth semiconductor chips 200B to 200D, and the step surfaces of an insulating body 320. Horizontal widths of the first anisotropic conductive elements 610 may be substantially the same as horizontal widths of the step surfaces of an insulating body 320.

The conductive particles 600P of the first anisotropic conductive elements 610 may be concentrated between the second to fourth input/output pads 210B to 210D, and the corresponding upper pads 310. As such, a conductive path may be formed by the conductive particles 600P of the first anisotropic conductive elements 610 between the second to fourth input/output pads 210B to 210D, and the corresponding upper pads 310. The first anisotropic conductive elements 610 may include an anisotropic conductive film (ACF), an anisotropic conductive paste (ACP), or the like.

The second anisotropic conductive elements 630 may be located between the circuit board 100 and a first semiconductor chip 200A, and between the circuit board 100 and the support structure 300. The second anisotropic conductive elements 630 may be located between a first signal pad 130A and a first input/output pad 210A, and between second to fourth signal pads 130B to 130D and lower pads 330. The second anisotropic conductive elements 630 may be in direct contact with an upper surface of the circuit board 100, a lower surface of the first semiconductor chip 200A, and a lower surface of the support structure 300. The second anisotropic conductive elements 630 may be separate from a first adhesive layer 220A. The second anisotropic conductive elements 630 may be extended along the upper surface of the circuit board 100.

The conductive particles 600P of the second anisotropic conductive element 630 may be concentrated between the first signal pad 130A and the first input/output pad 210A, and between the second to fourth signal pads 130B to 130D and the lower pads 330. A conductive path may be formed by the conductive particles 600P of the second anisotropic conductive element 630 between the first signal pad 130A and the first input/output pad 210A, and between the second to fourth signal pads 130B to 130D and the lower pads 330.

The second anisotropic conductive element 630 may include substantially the same material as the first anisotropic conductive elements 610. For example, the second anisotropic conductive element 630 may include an ACE. However, in another embodiment, the material of the first anisotropic conductive elements 610 and second anisotropic conductive element 630 may be different.

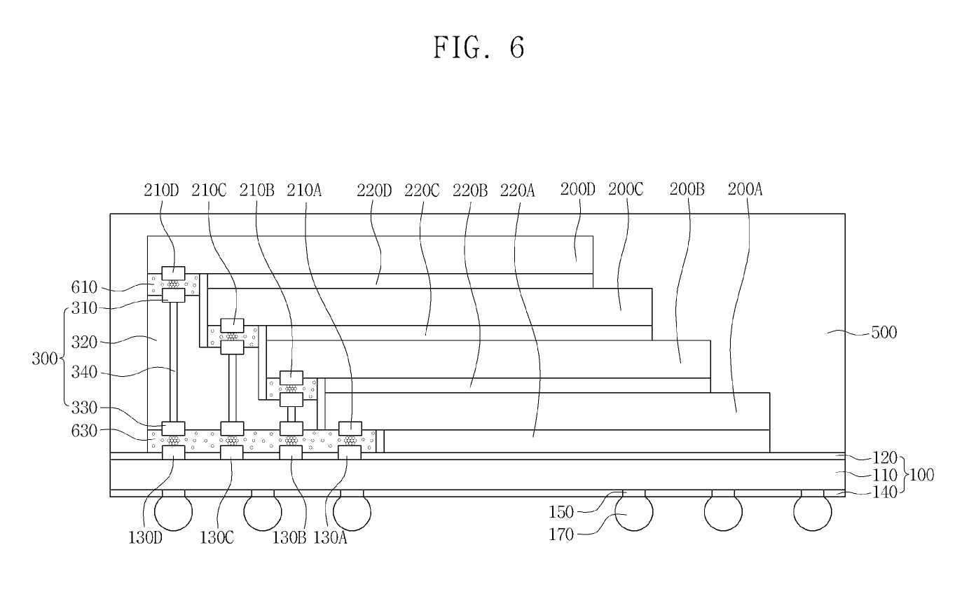

FIG. 6 is a cross-sectional view showing a semiconductor package according to yet another embodiment. Referring to FIG. 6, in an embodiment, a semiconductor package may include a circuit board 100, first to fourth semiconductor chips 200A to 200D, a support structure 300, a molding element 500, first anisotropic conductive elements 610, and a second anisotropic conductive element 630.

A level of an upper surface of the circuit board 100 may be lower than levels of upper surfaces of first to fourth signal pads 130A to 130D. The levels of the upper surfaces of the first to fourth signal pads 130A to 130D may be higher than a level of an upper surface of an upper insulating layer 120. The levels of the upper surfaces of the first to fourth signal pads 130A to 130D may be higher than a level of a lower surface of the second anisotropic conductive element 630. A thickness of each of the first to fourth signal pads 130A to 130D may be greater than that of the upper insulating layer 120. The first to fourth signal pads 130A to 130D may extend into the second anisotropic conductive element 630.

A level of a lower surface of each of the first to fourth semiconductor chips 200A to 200D may be higher than that of a lower surface of the corresponding one of first to fourth input/output pads 210A to 210D. For example, a level of a lower surface of a first input/output pad 210A may be lower than that of a lower surface of a first semiconductor chip 200A. The first input/output pad 210A may extend into the second anisotropic conductive element 630. Also, second to fourth input/output pads 210B to 210D may extend into the first anisotropic conductive elements 610.

A vertical distance between a level of an upper surface of a first signal pad 130A and the level of the lower surface of the first input/output pad 210A may be smaller than that between the level of the upper surfaces of the circuit board 100 and the level of the lower surface of the first semiconductor chip 200A.

A level of a lower surface of the insulating body 320 of the support structure 300 may be higher than levels of lower surfaces of lower pads 330. The lower pads 330 may extend into the second anisotropic conductive element 630.

A vertical distance between a level of an upper surface of each of second to fourth signal pads 130B to 130D and a level of a lower surface of the corresponding one of the lower pads 330 may be smaller than that between the level of the upper surface of the circuit board 100 and a level of a lower surface of an insulating body 320.

Each step surface of the insulating body 320 may be lower in level than an upper surface of the corresponding one of upper pads 310. The upper pads 310 may extend into the first anisotropic conductive elements 610.

A vertical distance between an upper surface of each of the upper pads 310 and a lower surface of the corresponding one of the second to fourth input/output pads 210B to 210D may be smaller than that between each of the step surfaces of the insulating body 320 and a lower surface of the corresponding one of second to fourth semiconductor chips 200B to 200D.

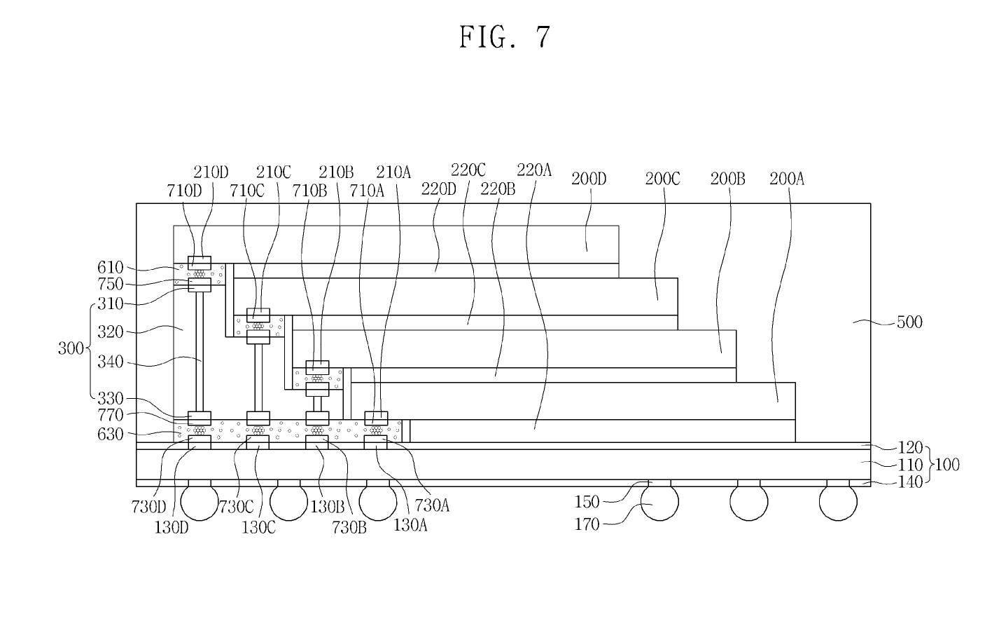

FIG. 7 is a cross-sectional view showing a semiconductor package according to yet another embodiment. Referring to FIG. 7, in an embodiment, a semiconductor package may include a circuit board 100, first to fourth semiconductor chips 200A to 200D, a support structure 300, a molding element 500, first anisotropic conductive elements 610, a second anisotropic conductive element 630, first to fourth chip magnetic pads 710A to 710D, first to fourth board magnetic pads 730A to 730D, upper magnetic pads 750, and lower magnetic pads 770.

The first to fourth chip magnetic pads 710A to 710D may be located on first to fourth input/output pads 210A to 210D, respectively. For example, a first chip magnetic pad 710A may be located on a first input/output pad 210A.

A level of a lower surface of each of the first to fourth chip magnetic pads 710A to 710D may be lower than that of a lower surface of the corresponding one of the first to fourth semiconductor chips 200A to 200D. For example, a level of a lower surface of a first chip magnetic pad 710A may be lower than that of a lower surface of a first semiconductor chip 200A. Accordingly, the second to fourth chip magnetic pads 710B to 710D may extend into the first anisotropic conductive elements 610 and the first chip magnetic pad 710A may extend into the second anisotropic conductive element 630.

A level of an upper surface of each of the first to fourth chip magnetic pads 710A to 710D may be substantially the same as that of a lower surface of the corresponding one of the first to fourth input/output pads 210A to 210D. The first to fourth chip magnetic pads 710A to 710D may be in direct contact with the first to fourth input/output pads 210A to 210D, respectively. The level of the upper surface of each of the first to fourth chip magnetic pads 710A to 710D may be substantially the same as that of the lower surface of the corresponding one of the first to fourth semiconductor chips 200A to 200D. For example, a level of an upper surface of the first chip magnetic pad 710A may be substantially the same as the level of the lower surface of the first semiconductor chip 200A.

The first to fourth chip magnetic pads 710A to 710D may include magnetic material. For example, the first to fourth chip magnetic pads 710A to 710D may include nickel (Ni), cobalt (Co), molybdenum (Mo), Iron (Fe), or the like.

The first to fourth board magnetic pads 730A to 730D may be located on first to fourth signal pads 130A to 130D, respectively. For example, a first board magnetic pad 730A may be located on a first signal pad 130A.

Levels of upper surfaces of the first to fourth board magnetic pads 730A to 730D may be higher than a level of an upper surface of the circuit board 100. Levels of lower surfaces of the first to fourth board magnetic pads 730A to 730D may be substantially the same as levels of upper surfaces of the first to fourth signal pads 130A to 130D. The first to fourth board magnetic pads 730A to 730D may be in direct contact with the first to fourth signal pads 130A to 130D, respectively. The levels of the lower surfaces of the first to fourth board magnetic pads 730A to 730D may be substantially the same as the level of the upper surface of the circuit board 100. The levels of the lower surfaces of the first to fourth board magnetic pads 730A to 730D may be substantially the same as a level of an upper surface of an upper insulating layer 120. The first to fourth board magnetic pads 730A to 730D may extend into the second anisotropic conductive element 630.

The first to fourth board magnetic pads 730A to 730D may include magnetic material. For example, the first to fourth board magnetic pads 730A to 730D may include substantially the same material as the first to fourth chip magnetic pads 710A to 710D. However, in another embodiment, the material of the first to fourth board magnetic pads 730A to 730D and the first to fourth chip magnetic pads 710A to 710D may be different.

The upper magnetic pads 750 may be located on the upper pads 310, respectively. An upper surface of each of the upper magnetic pads 750 may be higher in level than the corresponding one of step surfaces of an insulating body 320. A lower surface of each of the upper magnetic pads 750 may be substantially the same as the corresponding one of step surfaces of an insulating body 320. The upper magnetic pads 750 may be in direct contact with the upper pads 310, respectively. Accordingly, the upper magnetic pads 750 may extend into the first anisotropic conductive elements 610.

The lower magnetic pads 770 may be located on lower pads 330, respectively. Levels of lower surfaces of the lower magnetic pads 770 may be lower than a level of a lower surface of the insulating body 320. Levels of upper surfaces of the lower magnetic pads 770 may be substantially the same as the level of the lower surface of the insulating body 320. The lower magnetic pads 770 may be in direct contact with the lower pads 330, respectively. Accordingly, the lower magnetic pads 770 may extend into the second anisotropic conductive element 630.

The upper magnetic pads 750 and the lower magnetic pads 770 may include magnetic material. For example, the upper magnetic pads 750 and the lower magnetic pads 770 may include substantially the same material as the first to fourth chip magnetic pads 710A to 710D. The upper magnetic pads 750 may include substantially the same material as the lower magnetic pads 770. However, in another embodiment, the upper magnetic pads 750, the lower magnetic pads 770, the first to fourth chip magnetic pads 710A to 710D, the first to fourth board magnetic pads 730A to 730D, or the like can have different materials.

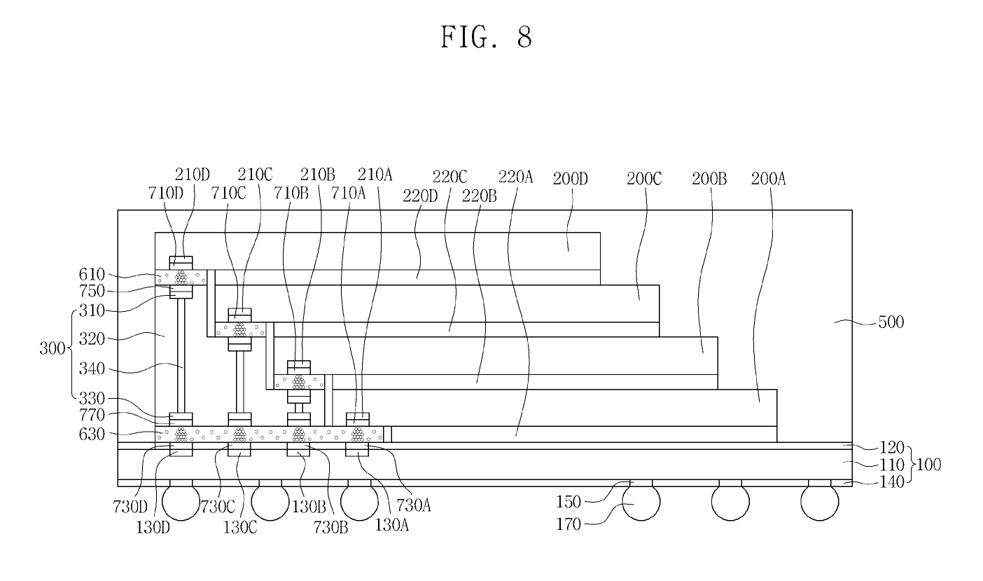

FIG. 8 is a cross-sectional view showing a semiconductor package according to yet another embodiment. Referring to FIG. 8, in an embodiment, a semiconductor package may include a circuit board 100, first to fourth semiconductor chips 200A to 200D, a support structure 300, a molding element 500, first anisotropic conductive elements 610, a second anisotropic conductive element 630, first to fourth chip magnetic pads 710A to 710D, first to fourth board magnetic pads 730A to 730D, upper magnetic pads 750, and lower magnetic pads 770.

Levels of upper surfaces of the first to fourth chip magnetic pads 710A to 710D may be substantially the same as that of lower surfaces of the first to fourth semiconductor chips 200A to 200D.

Levels of upper surfaces of the first to fourth board magnetic pads 730A to 730D may be substantially the same as a level of an upper surface of the circuit board 100. Levels of lower surfaces of the first to fourth board magnetic pads 730A to 730D may be substantially the same as a level of an upper surface of a board body 110. Levels of upper surfaces of first to fourth signal pads 130A to 130D may be substantially the same as a level of a lower surface of an upper insulating layer 120.

Upper surfaces of the upper magnetic pads 750 may be substantially the same level as step surfaces of an insulating body 320. Levels of lower surfaces of the lower magnetic pads 770 may be substantially the same as a level of a lower surface of the insulating body 320.

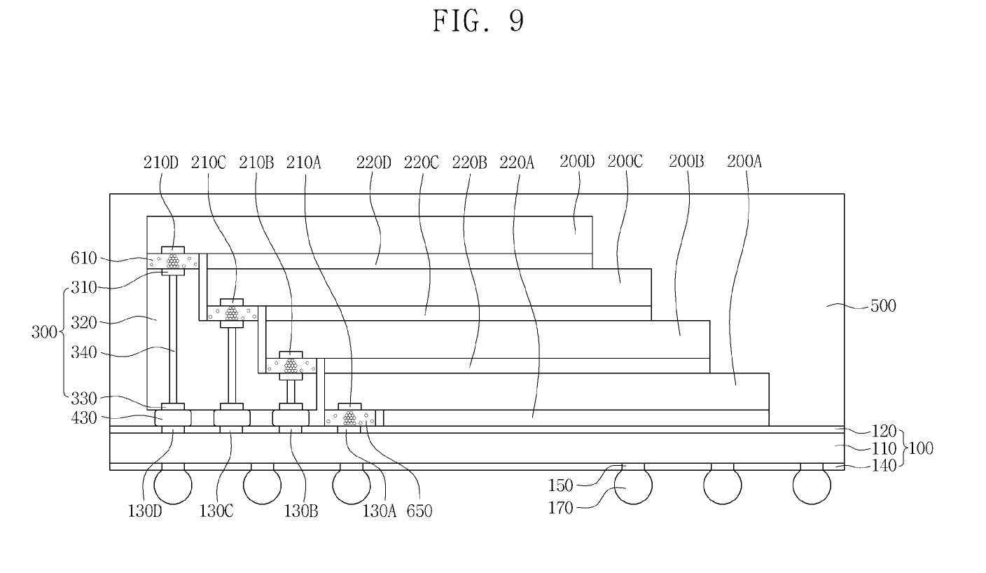

FIG. 9 is a cross-sectional view showing a semiconductor package according to yet another embodiment. Referring to FIG. 9, in an embodiment a semiconductor package may include a circuit board 100, first to fourth semiconductor chips 200A to 200D, a support structure 300, second connection elements 430, a molding element 500, first anisotropic conductive elements 610, and a third anisotropic conductive element 650.

The third anisotropic conductive element 650 may be located between a first signal pad 130A and a first input/output pad 210A. The third anisotropic conductive element 650 may be separate from a first adhesive layer 220A. The third anisotropic conductive element 650 may be in direct contact with an upper surface of the circuit board 100 and a lower surface of a first semiconductor chip 200A.

The third anisotropic conductive element 650 may include a conductive path connecting the first signal pad 130A and the first input/output pad 210A. The third anisotropic conductive element 650 may include substantially the same material as the first anisotropic conductive elements 610.

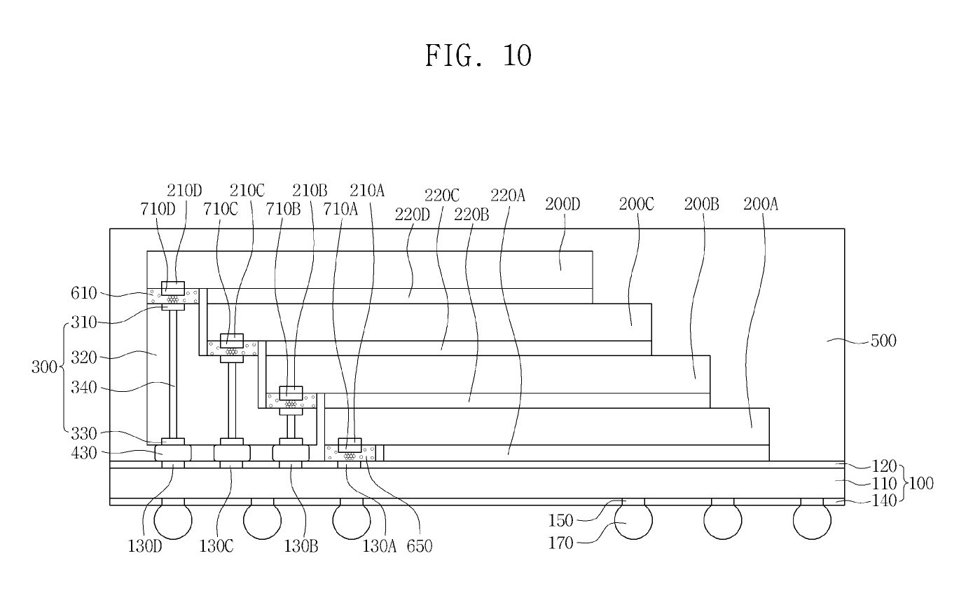

FIG. 10 is a cross-sectional view showing a semiconductor package according to yet another embodiment. Referring to FIG. 10, in an embodiment, a semiconductor package may include a circuit board 100, first to fourth semiconductor chips 200A to 200D, a support structure 300, second connection elements 430, a molding element 500, first anisotropic conductive elements 610, a third anisotropic conductive element 650, and first to fourth chip magnetic pads 710A to 710D. A level of a lower surface of each of the first to fourth chip magnetic pads 710A to 710D may be lower than that of a lower surface of the corresponding one of the first to fourth semiconductor chips 200A to 200D.

A first chip magnetic pad 710A may face a first signal pad 130A. The third anisotropic conductive element 650 may be in direct contact with the first signal pad 130A and the first chip magnetic pad 710A. A level of an upper surface of the first signal pad 130A may be substantially the same as a level of an upper surface of the circuit board 100.

Second to fourth chip magnetic pads 710B to 710D may face upper pads 310, respectively. Each of the first anisotropic conductive elements 610 may be in direct contact with the corresponding one of the second to fourth chip magnetic pads 710B to 710D, and the corresponding one of the upper pads 310. Upper surfaces of the upper pads 310 may be substantially the same as levels of step surfaces of an insulating body 320.

As illustrated in FIGS. 9 and 10, in an embodiment, within a semiconductor package, a variety of different connection techniques can be used to couple the signal pads 130, lower pads 330, upper pads 310, and input/output pads 210.

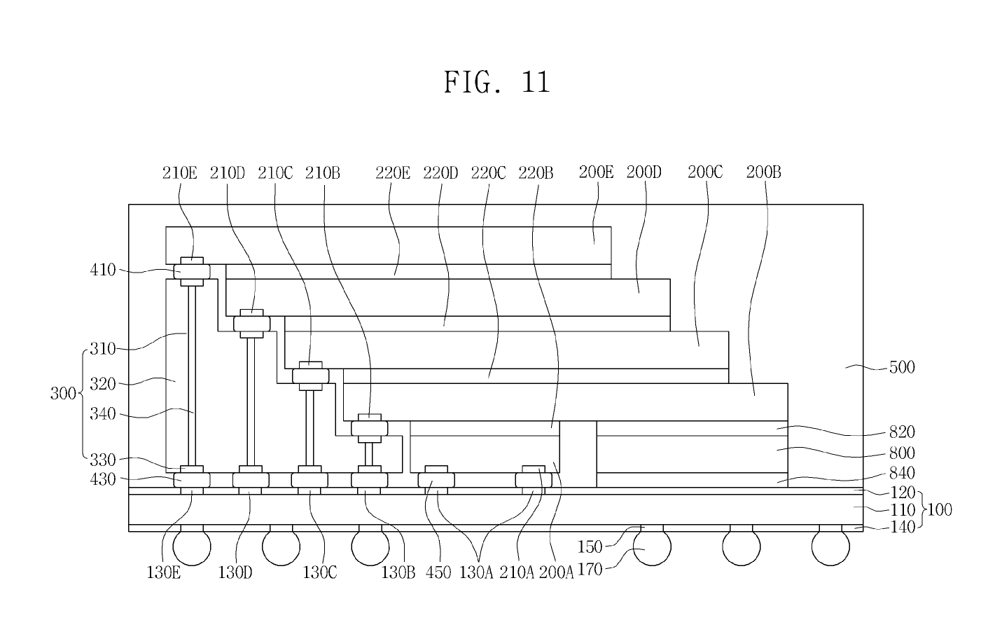

FIG. 11 is a cross-sectional view showing a semiconductor package according to yet another embodiment. Referring to FIG. 11, in an embodiment, a semiconductor package may include a circuit board 100, first to fifth semiconductor chips 200A to 200E, a support structure 300, first connection elements 410, second connection elements 430, third connection elements 450, a molding element 500, and a chip supporting element 800.

A first semiconductor chip 200A may be different from second to fifth semiconductor chips 200B to 200E. A horizontal width of the first semiconductor chip 200A may be smaller than that of each of the second to fifth semiconductor chips 200B to 200E. The first semiconductor chip 200A may have first input/output pads 210A respectively in both side portions thereof. For example, the first semiconductor chip 200A may be a logic chip, such as a controller.

The chip supporting element 800 may support the second to fifth semiconductor chips 200B to 200E, which are sequentially stacked on the circuit board 100. The chip supporting element 800 may be located between the circuit board 100 and a second semiconductor chip 200B. The second support structure 800 may be separate from the first semiconductor chip 200A. For example, a right side surface of the chip supporting element 800 may be aligned (e.g., vertically aligned) with a right side surface of the second semiconductor chip 200B.

A vertical height of the chip supporting element 800 may be substantially the same in size as a thickness of the first semiconductor chip 200A. For example, the chip supporting element 800 may be a dummy chip.

The semiconductor package according to yet another embodiment may further include an upper adhesive layer 820 located on an upper surface of the chip supporting element 800, and a lower adhesive layer 840 located on a lower surface of the chip supporting element 800.

The upper adhesive layer 820 may cover the upper surface of the chip supporting element 800. The upper adhesive layer 820 may be in direct contact with a lower surface of the semiconductor chip 200B and the upper surface of the chip supporting element 800.

A thickness of the upper adhesive layer 820 may be substantially the same as a thickness of a second adhesive layer 220B. The upper adhesive layer 820 may be substantially the same material as the second to fifth adhesive layers 220B to 220E.

The lower adhesive layer 840 may cover the lower surface of the chip supporting element 800. The lower adhesive layer 840 may be in direct contact with an upper surface of the circuit board 100 and the lower surface of the chip supporting element 800.

A thickness of the lower adhesive layer 840 may be substantially the same in size as a vertical distance between the circuit board 100 and the first semiconductor chip 200A. The thickness of the lower adhesive layer 840 may be substantially the same as a thickness of the third connection element 450. The lower adhesive layer 840 may include substantially the same material as the upper adhesive layer 820.

Although a single chip supporting element 800 has been illustrated, the semiconductor package may include any number of support structures 300 and chip supporting element 800 as desired.

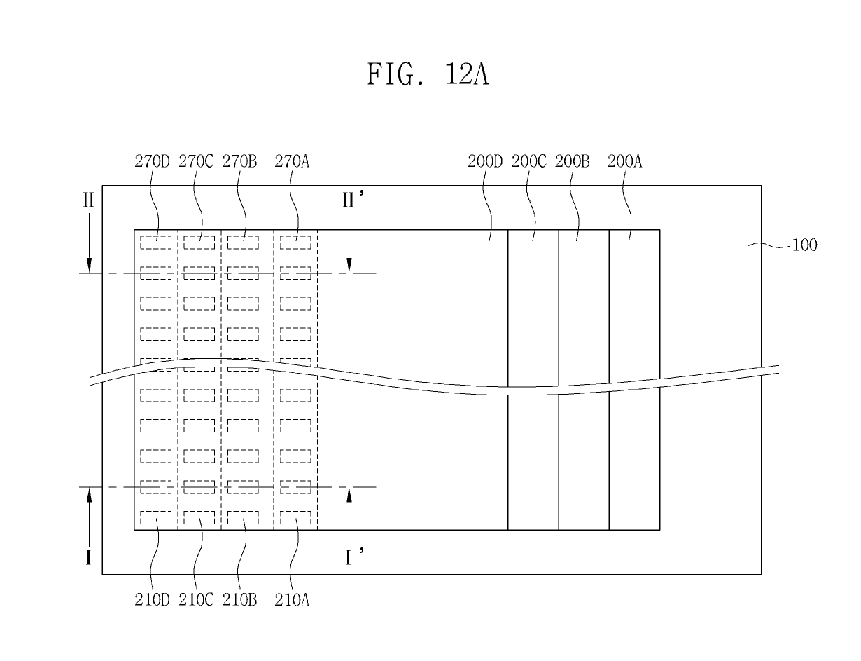

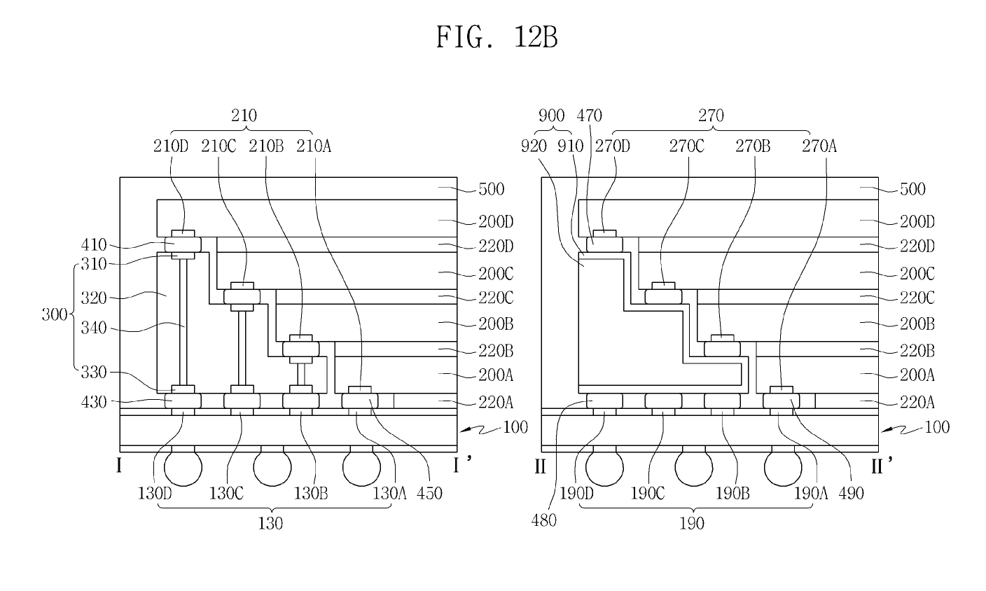

FIG. 12A is a plan view showing a semiconductor package according to yet another embodiment, and FIG. 12B is a cross-sectional view taken along lines I-I′ and II-II′ of FIG. 12A. Referring to FIGS. 12A and 12B, in an embodiment, a semiconductor package may include a circuit board 100, first to fourth semiconductor chips 200A to 200D, a support structure 300, a molding element 500, and a connection structure 900.

The first to fourth semiconductor chips 200A to 200D may include input/output pads 210 and chip pads 270 located in lower surfaces thereof. The input/output pads 210 and the chip pads 270 may be located in substantially the same side of surfaces of the first to fourth semiconductor chips 200A to 200D. The input/output pads 210 and the chip pads 270 may be located to be distinguished from each other. For example, the input/output pads 210 may be located in lower portions of left sides of the surfaces of the first to fourth semiconductor chips 200A to 200D, and the chip pads 270 may be located in upper portions of the left sides of the surfaces of the first to fourth semiconductor chips 200A to 200D.

For convenience of illustration, the chip pads 270 may be referred to as a first chip pad 270A, a second chip pad 270B, a third chip pad 270C, and a fourth chip pad 270D, depending on the positional relationship with the first to fourth semiconductor chips 200A to 200D. For example, the first chip pad 270A may be located in a lower surface of a first semiconductor chip 200A.

Levels of lower surfaces of the chip pads 270 may be substantially the same as those of lower surfaces of the input/output pads 210. A level of a lower surface of each of the chip pads 270 may be substantially the same as that of a lower surface of the corresponding one of the first to fourth semiconductor chips 200A to 200D. For example, a level of a lower surface of the first chip pad 270A may be substantially the same as that of the lower surface of the first semiconductor chip 200A.

The chip pads 270 may include conductive material. For example, the chip pads 270 may include gold (Au), silver (Ag), copper (Cu), nickel (Ni), aluminum (Al), or the like. The chip pads 270 may include substantially the same material as the input/output pads 210.

The circuit board 100 may include signal pads 130 and board pads 190. The signal pads 130 and the board pads 190 are disposed on the upper surface of the circuit board 100. The board pads 190 may be configured to transmit a common signal to the first to fourth semiconductor chips 200A to 200D. For example, the board pads 190 may be configured to transmit a power voltage or a ground voltage to the first to fourth semiconductor chips 200A to 200D.

The board pads 190 may be aligned (e.g., vertically aligned) with the chip pads 270, such that the board pads 190 horizontally overlap with the chip pads 270. For convenience of illustration, the board pads 190 may be referred to as a first board pad 190A, a second board pad 190B, a third board pad 190C, and a fourth board pad 190D, depending on the positional relationship with the chip pads 270. For example, the first board pad 190A may be aligned (e.g., vertically aligned) with the first chip pad 270A. The first board pad 190A may face the first chip pad 270A.

The connection structure 900 may support exposed lower surfaces of second to fourth semiconductor chips 200B to 200D which are stacked in a terraced configuration on the circuit board 100. The connection structure 900 may electrically connect second to fourth board pads 190B to 190D to the second to fourth semiconductor chips 200B to 200D. The connection structure 900 may be located between the second to fourth board pads 190B to 190D and the exposed lower surfaces of the second to fourth semiconductor chips 200B to 200D.

The connection structure 900 may include a connection line 910, and a connection body 920. The connection line 910 may be located on a lower surface and an upper surface of the connection body 920. The connection line 910 may be extended along a surface of the connection body 920. The connection line 910 may, but need not be located on a portion of the surface of the connection body 920 that does not face the first to fourth semiconductor chips 200A to 200D.

The connection line 910 may be electrically connected to the second to fourth semiconductor chips 200B to 200D. The connection line 910 may be electrically connected to second to fourth chip pads 270B to 270D. The connection line 910 may be electrically connected to the second to fourth board pads 190B to 190D. The connection line 910 may electrically connect the second to fourth chip pads 270B to 270D, and the second to fourth board pads 190B to 190D.

The connection line 910 may include conductive material. For example, the connection line 910 may include gold (Au), silver (Ag), copper (Cu), nickel (Ni), aluminum (Al), or the like.

The connection body 920 may support the exposed lower surfaces of the second to fourth semiconductor chips 200B to 200D. The connection body 920 may be located between the second to fourth board pads 190B to 190D and the second to fourth chip pads 270B to 270D.

An upper surface of the connection body 920 may have a terraced shape. Step surfaces of the connection body 920 may face the second to fourth semiconductor chips 200B to 200D, respectively. The connection line 910 may have a terraced shape including step surfaces which face the second to fourth chip pads 270B to 270D. A lower surface of the connection body 920 may be parallel to an upper surface of the circuit board 100. For example, the connection body 920 may be substantially the same shape as an insulating body 320 of the support structure 300.

The connection body 920 may include insulating material. For example, the connection body 920 may include substantially the same material as the insulating body 320.

In an embodiment, the semiconductor package may further include fourth connection elements 470 located between the second to fourth chip pads 270B to 270D and the step surfaces of the connection line 910, fifth connection elements 480 located between the second to fourth board pads 190B to 190D and the connection line 910, and a sixth connection element 490 located between the first board pad 190A and the first chip pad 270A.

The fourth connection elements 470 may be in direct contact with the step surfaces of the connection line 910, and the second to fourth chip pads 270B to 270D. The fourth connection elements 470 may be in direct contact with the exposed lower surfaces of the second to fourth semiconductor chips 200B to 200D.

The fifth connection elements 480 may be in direct contact with the second to fourth board pads 190B to 190D, and the connection line 910. The fifth connection elements 480 may be in direct contact with the upper surface of the circuit board 100. The fifth connection elements 480 may be separated from each other.

The sixth connection element 490 may be in direct contact with the first board pad 190A and the first chip pad 270A. The sixth connection element 490 may be in direct contact with the upper surface of the circuit board 100 and the lower surface of the first semiconductor chip 200A. The sixth connection element 490 may be separate from the fifth connection elements 480. The sixth connection element 490 may be separate from a first adhesive layer 220A.

Fourth to sixth connection elements 470 to 490 may include substantially the same material. The fourth to sixth connection elements 470 to 490 may include substantially the same material as first to third connection elements 410, 430 and 450. For example, the fourth to sixth connection elements 470 to 490 may include a solder ball.

The molding element 500 may cover the connection structure 900. The molding element 500 may surround the fourth to sixth connection elements 470 to 490. The molding element 500 may fill spaces between the circuit board 100 and the connection structure 900, and between the first to fourth semiconductor chips 200A to 200D and the connection structure 900.

In an embodiment, the connection structure 900 and the connector structure 300 can be coupled together. For example, the connection body 920 and insulating body 320 may be substantially the same structure. However, input/output pads 310, lower pads 330, and the connection line 910 may be disposed at different locations as appropriate for the connections to the pads 210 and 270 of the semiconductor chips 200.

In another embodiment, the connection structure 900 and the connector structure 300 may be separate. For example, just as the first support structure 301 and the second support structure 302 may be separate yet coupled to the same semiconductor chips 200, so may the connection structure 900 and the connector structure 300 be separate.

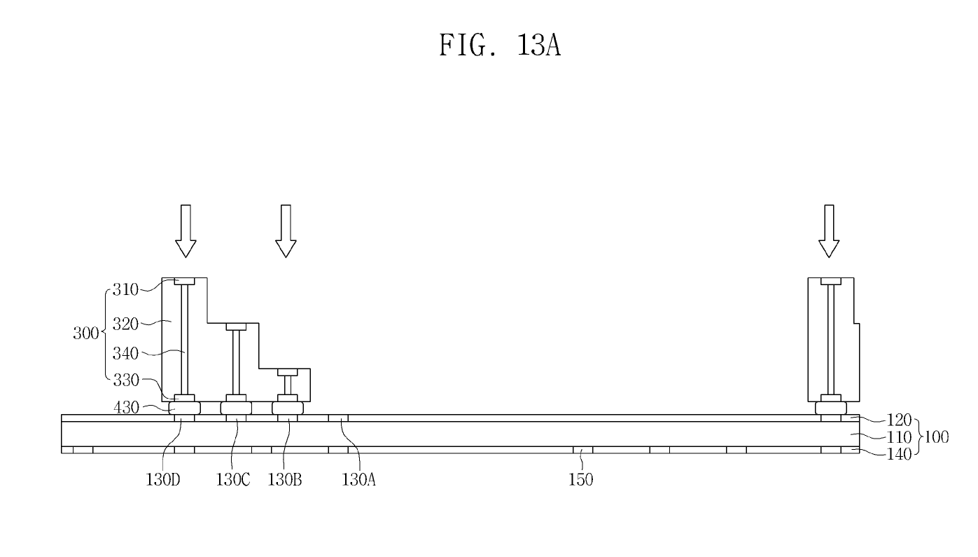

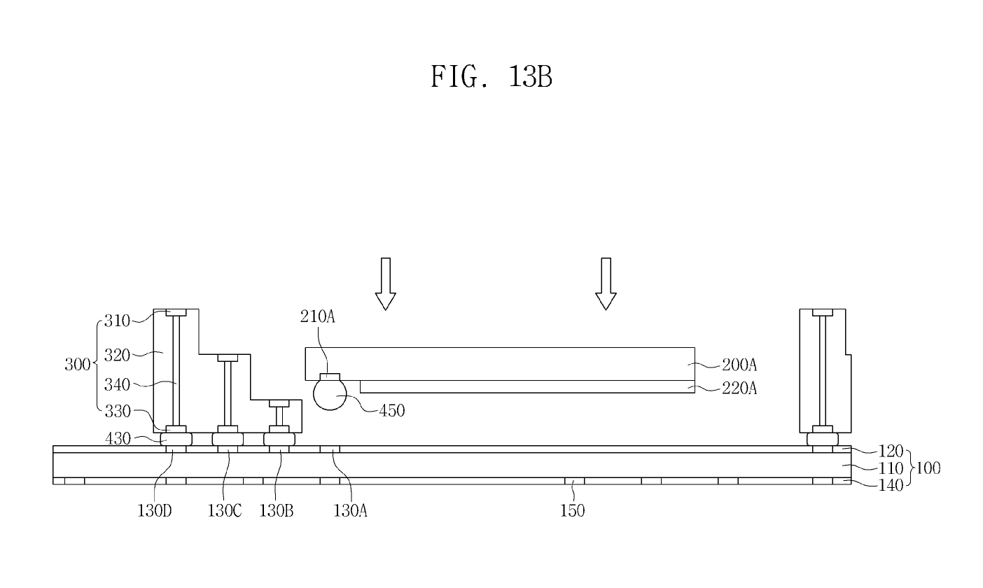

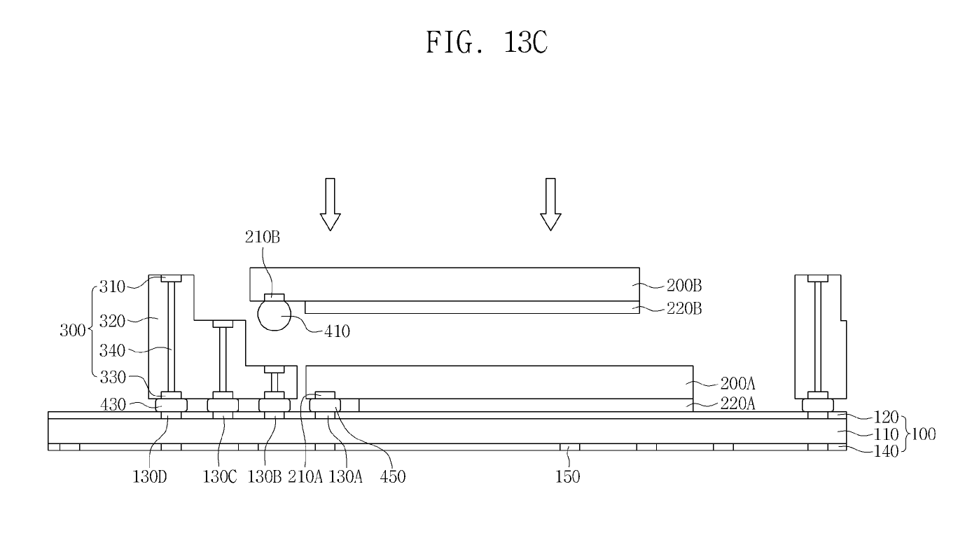

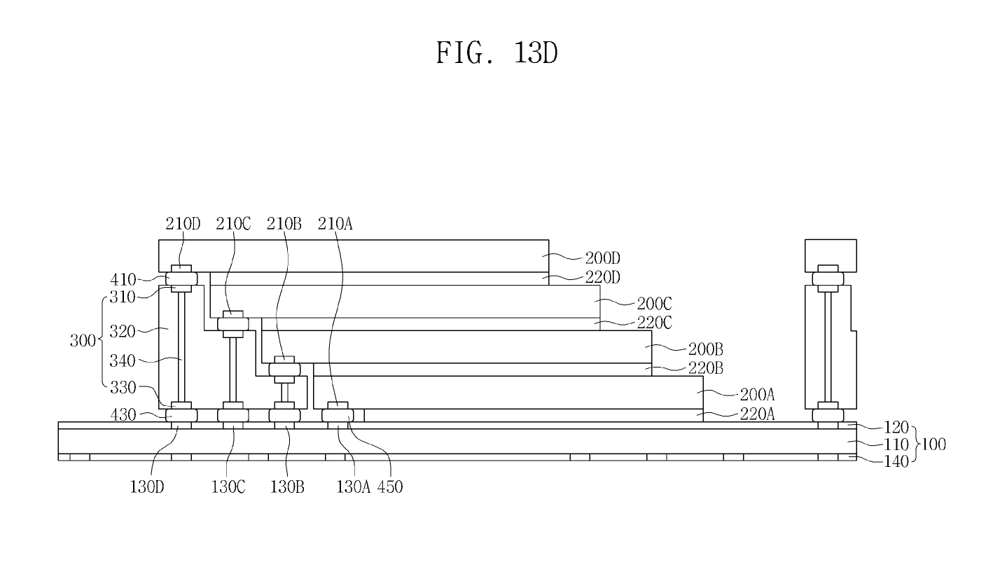

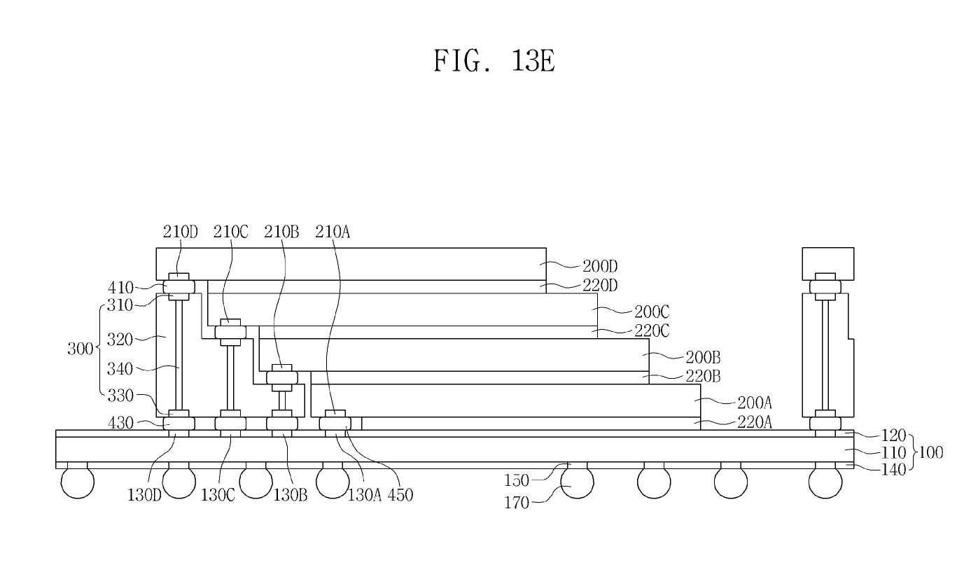

FIGS. 13A to 13F are cross-sectional views sequentially illustrating a method of fabricating a semiconductor package according to an embodiment. The method of fabricating the semiconductor package according to an embodiment may be illustrated by referring to FIGS. 1A, 1B, and 13A to 13F.

Firstly referring to FIG. 13A, the method of fabricating the semiconductor package may include attaching a support structure 300 to an upper surface of a circuit board 100. Attaching the support structure 300 to the upper surface of the circuit board 100 may include attaching the support structure 300 to the upper surface of the circuit board 100 using second connection elements 430.

Attaching the support structure 300 to the upper surface of the circuit board 100 may include attaching lower pads 330 of the support structure 300 to second to fourth signal pads 130B to 130D using the second connection elements 430, respectively.

Referring to FIG. 13B, the method may include mounting a first semiconductor chip 200A on the upper surface of the circuit board 100. Mounting the first semiconductor chip 200A on the upper surface of the circuit board 100 may include preparing the first semiconductor chip 200A including a first input/output pad 210A, forming a third connection element 450 on the first input/output pad 210A, aligning the first semiconductor chip 200A on the upper surface of the circuit board 100, and attaching the first semiconductor chip 200A to the upper surface of the circuit board 100 using a first adhesive layer 220A and the third connection element 450.

The aligning the first semiconductor chip 200A on the upper surface of the circuit board 100 may include aligning the first semiconductor chip 200A to face a first signal pad 130A of the circuit board 100 and the first input/output pad 210A. The aligning the first semiconductor chip 200A on the upper surface of the circuit board 100 may include aligning the first signal pad 130A and the first input/output pad 210A.

The attaching the first semiconductor chip 200A to the upper surface of the circuit board 100 using the first adhesive layer 220A and the third connection element 450 may include electrically connecting the first signal pad 130A and the first input/output pad 210A using the third connection element 450.

Referring to FIG. 13C, the method may include offset stacking a second semiconductor chip 200B on an upper surface of the first semiconductor chip 200A. The offset stacking the second semiconductor chip 200B on the upper surface of the first semiconductor chip 200A may include preparing the second semiconductor chip 200B including a second input/output pad 210B, forming a first connection element 410 on the second input/output pad 210B, aligning the second semiconductor chip 200B on the upper surface of the circuit board 100, and attaching the second semiconductor chip 200B on the upper surface of the first semiconductor chip 200A using a second adhesive layer 220B and the first connection element 410.

The aligning the second semiconductor chip 200B on the upper surface of the circuit board 100 may include aligning the second signal pad 130B and the second input/output pad 210B.

The attaching the second semiconductor chip 200B on the upper surface of the first semiconductor chip 200A using the second adhesive layer 220B and the first connection element 410 may include electrically connecting the second input/output pad 210B to the corresponding one of upper pads 310 using the first connection element 410.

Referring to FIG. 13D, the method may include sequentially offset stacking a third semiconductor chip 200C and a fourth semiconductor chip 200D on an upper surface of the second semiconductor chip 200B. The sequentially offset stacking the third semiconductor chip 200C and the fourth semiconductor chip 200D on the upper surface of the second semiconductor chip 200B may include offset stacking the third semiconductor chip 200C on the upper surface of the second semiconductor chip 200B, and offset stacking the fourth semiconductor chip 200D on an upper surface of the third semiconductor chip 200C.

The offset stacking the third semiconductor chip 200C on the upper surface of the second semiconductor chip 200B may include preparing the third semiconductor chip 200C including a third input/output pad 210C, forming a first connection element 410 on the third input/output pad 210C, aligning the third semiconductor chip 200C on the circuit board 100, and attaching the third semiconductor chip 200C to the upper surface of the second semiconductor chip 200B using a third adhesive layer 220C and the first connection element 410.

The aligning the third semiconductor chip 200C on the circuit board 100 may include aligning a third signal pad 130C and the third input/output pad 210C.

The attaching the third semiconductor chip 200C to the upper surface of the second semiconductor chip 200B using the third adhesive layer 220C and the first connection element 410 may include electrically connecting the third input/output pad 210C to the corresponding one of the upper pads 310 using the first connection element 410.

The offset stacking the fourth semiconductor chip 200D on the upper surface of the third semiconductor chip 200C may include preparing the fourth semiconductor chip 200D including a fourth input/output pad 210D, forming a first connection element 410 on the fourth input/output pad 210D, aligning the fourth semiconductor chip 200D on the circuit board 100, and attaching the fourth semiconductor chip 200D to an upper surface of the third semiconductor chip 200C using a fourth adhesive layer 220D and the first connection element 410.

The aligning the fourth semiconductor chip 200D on the circuit board 100 may include aligning a fourth signal pad 130D and the fourth input/output pad 210D.

The attaching the fourth semiconductor chip 200D to the upper surface of the third semiconductor chip 200C using the fourth adhesive layer 220D and the first connection element 410 may include electrically connecting the fourth input/output pad 210D to the corresponding one of the upper pads 310 using the first connection element 410.

Referring to FIG. 13E, the method may include forming external terminals 170 on terminal pads 150 of the circuit board 100.

When the first connection elements 410, the second connection elements 430 and the third connection element 450 are a solder ball, the method may further include reflowing the first connection elements 410, the second connection elements 430 and the third connection element 450

Referring to FIG. 13F, the method may include forming a molding element 500 on the upper surface of the circuit board 100. The forming the molding element 500 on the upper surface of the circuit board 100 may include covering the first to fourth semiconductor chips 200A to 200D, and the support structure 300. The upper surface of the circuit board 100 may be covered with the molding element 500. The first connection elements 410, the second connection elements 430 and the third connection element 450 may be surrounded by the molding element 500. Spaces between the circuit board 100 and the first to fourth semiconductor chips 200A to 200D, between the first to fourth semiconductor chips 200A to 200D and the support structure 300, between the circuit board 100 and the support structure 300, or the like may be covered with the molding element 500.

The molding element 500 may completely fill the spaces between the circuit board 100, the first to fourth semiconductor chips 200A to 200D and the support structure 300. The molding element 500 may include material having high fluidity. The molding element 500 may be relatively soft as compared with an insulating body 320.

According to the method, after the insulating body 320 is formed to surround conductive pillars 340, the molding element 500 may be formed to surround the insulating body 320. As such, in the method, the conductive pillars 340 may be prevented from being flowed due to the formation of the molding element 500. That is, in the method, electrical connections between the input/output pads 210A, 210B, 210C and 210D of the semiconductor chips 200A, 200B, 200C and 200D and the signal pads 130A, 130B, 130C and 130D of the circuit board 100 may be prevented from being unstable due to the formation of the molding element 500. As a result, in the method, reliability of the semiconductor chips 200A, 200B, 200C and 200D may be increased.

Also, the method may further include hardening the molding element 500 hard. In the method, the insulating body 320 may already be hardened so as to cover the conductive pillars 340. As such, in the method, the insulating body 320 may be harder than the molding element 500.

Referring to FIGS. 1A and 1B, the method may include cutting the circuit board 100 and the molding element 500 to form a unit package. The cutting the circuit board 100 and the molding element 500 may include a sawing process.

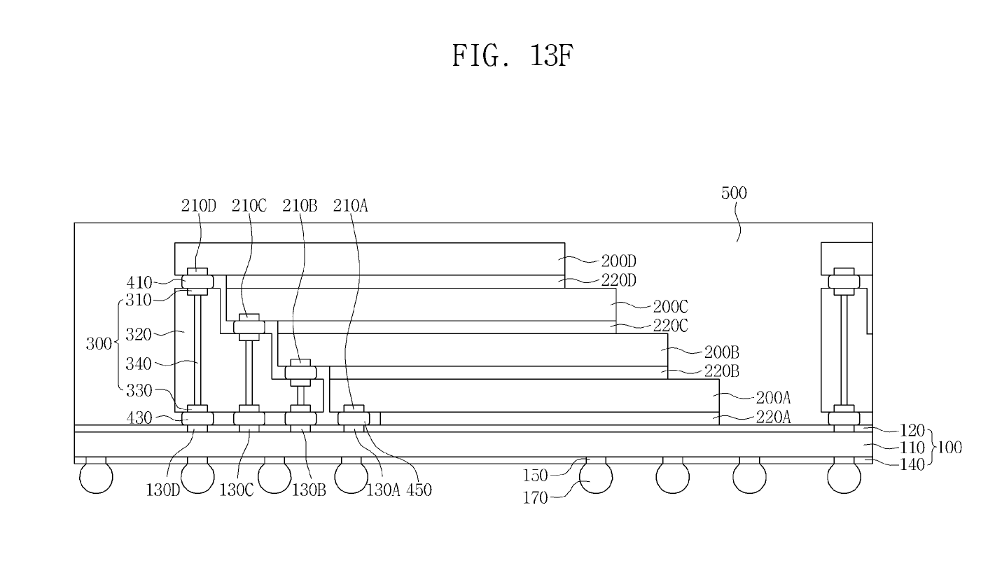

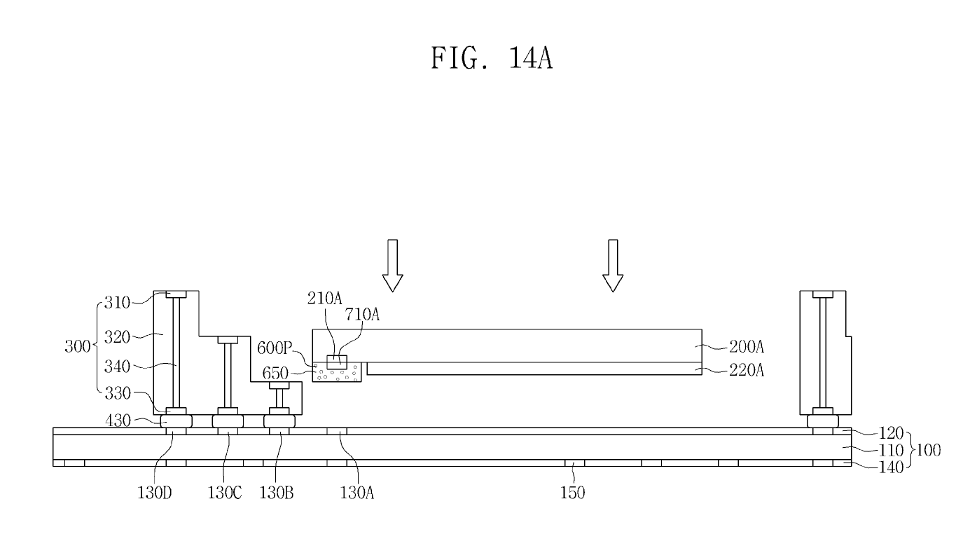

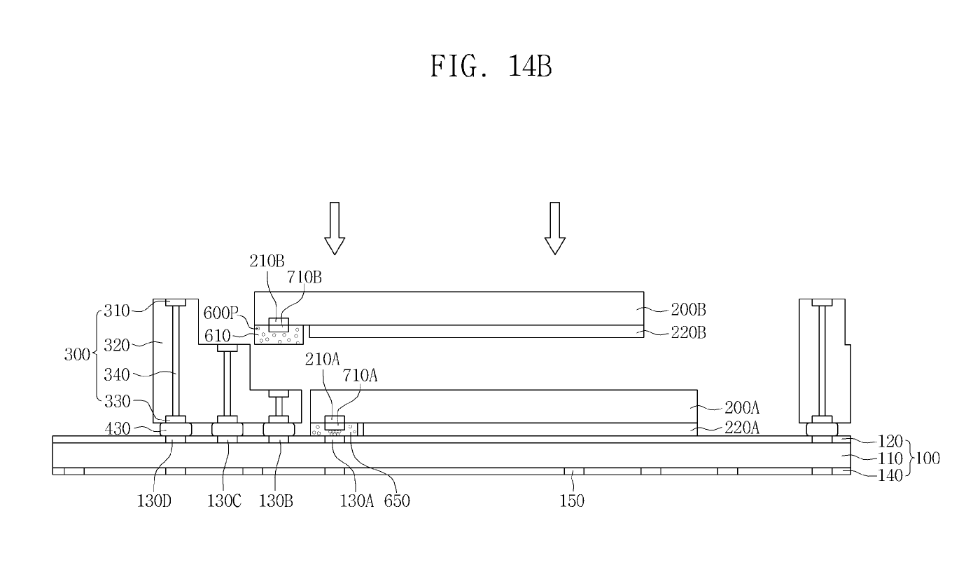

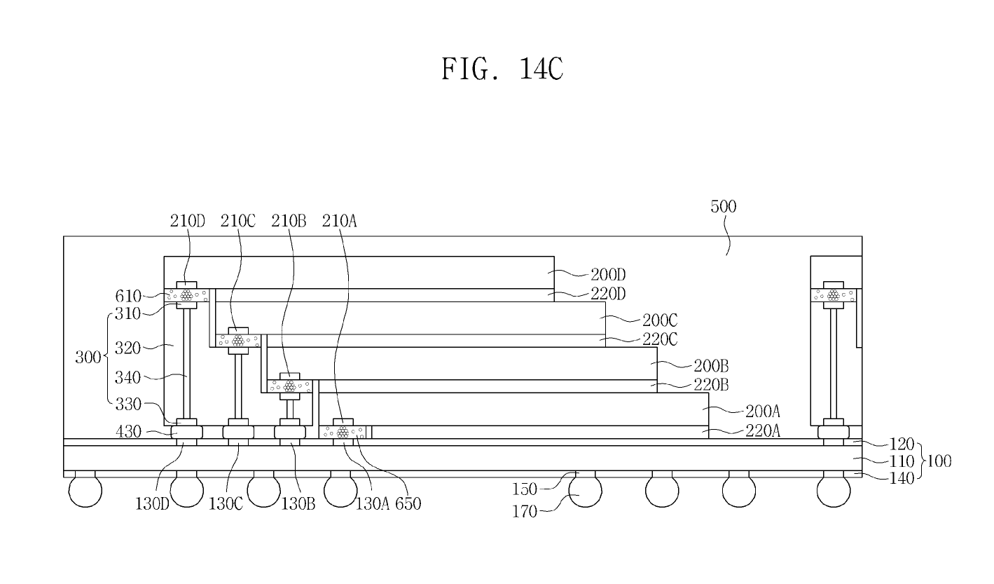

FIGS. 14A to 14C are cross-sectional views sequentially illustrating a method of fabricating a semiconductor package according to another embodiment. The method of fabricating the semiconductor package according to another embodiment may be illustrated by referring to FIGS. 9, and 14A to 14C.

Referring to FIG. 14A, in an embodiment, the method of fabricating the semiconductor package may include mounting a first semiconductor chip 200A on an upper surface of a circuit board 100 to which a support structure 300 is attached.

The mounting the first semiconductor chip 200A on the upper surface of the circuit board 100 may include preparing the first semiconductor chip 200A including a first input/output pad 210A, forming a magnetic pad 710A on the first input/output pad 210A, forming a third anisotropic conductive element 650 covering the magnetic pad 710A, aligning the first semiconductor chip 200A on the upper surface of the circuit board 100 to face a first signal pad 130A and the magnetic pad 710A, and attaching the first semiconductor chip 200A to the upper surface of the circuit board 100 using a first adhesive layer 220A and the third anisotropic conductive element 650.

The magnetic pad 710A may protrude from a lower surface of the first semiconductor chip 200A. The third anisotropic conductive element 650 may cover a portion of the lower surface of the first semiconductor chip 200A. The third anisotropic conductive element 650 may be separate from the first adhesive layer 220A.

The forming the third anisotropic conductive element 650 may include coating an anisotropic conductive paste (ACP) including conductive particles 600P, so as to cover the magnetic pad 710A on the lower surface of the first semiconductor chip 200A.

The attaching the first semiconductor chip 200A to the upper surface of the circuit board 100 using the first adhesive layer 220A and the third anisotropic conductive element 650 may include connecting the first signal pad 130A and the first input/output pad 210A using the third anisotropic conductive element 650.

The mounting the first semiconductor chip 200A on the upper surface of the circuit board 100 may include forming the third anisotropic conductive element 650 thicker than the first adhesive layer 220A on the lower surface of the first semiconductor chip 200A, and pressurizing the third anisotropic conductive element 650 to concentrate the conductive particles 600P and form a conductive path between the first signal pad 130A and the magnetic pad 710A.

Referring to FIG. 14B, the method may include offset stacking a second semiconductor chip 200B on an upper surface of the first semiconductor chip 200A. The process of offset stacking the second semiconductor chip 200B on the upper surface of the first semiconductor chip 200A may include preparing the second semiconductor chip 200B including a second input/output pad 210B, forming a second magnetic pad 710B on the second input/output pad 210B, forming a first anisotropic conductive element 610 covering the second magnetic pad 710B, aligning the second semiconductor chip 200B on the upper surface of the circuit board 100, and attaching the second semiconductor chip 200B to the upper surface of the first semiconductor chip 200A using a second adhesive layer 220B and the first anisotropic conductive element 610.

The attaching the second semiconductor chip 200B to the upper surface of the first semiconductor chip 200A using the second adhesive layer 220B and the first anisotropic conductive element 610 may include connecting the second input/output pad 210B to the corresponding one of the upper pads 310 using the first anisotropic conductive element 610.

Referring to FIG. 14C, the method may include sequentially offset stacking a third semiconductor chip 200C and a fourth semiconductor chip 200D on an upper surface of the second semiconductor chip 200B, forming external terminals 170, and forming a molding element 500. The sequentially offset stacking the third semiconductor chip 200C and the fourth semiconductor chip 200D on the upper surface of the second semiconductor chip 200B may include offset stacking the third semiconductor chip 200C on the upper surface of the second semiconductor chip 200B, and offset stacking the fourth semiconductor chip 200D on an upper surface of the third semiconductor chip 200C.

Forming the molding element 500 may include covering the first to fourth semiconductor chips 200A to 200D and the support structure 300 with the molding element 500. Second connection elements 430, the first anisotropic conductive elements 610, and the third anisotropic conductive element 650 may be surrounded by the molding element 500. Spaces between the second connection elements 430, the first anisotropic conductive elements 610, and the third anisotropic conductive element 650 may be filled with the molding element 500.

Referring to FIG. 9, the method may include cutting the circuit board 100 and the molding element 500 to form a unit package. The cutting the circuit board 100 and the molding element 500 may include using a sawing process.

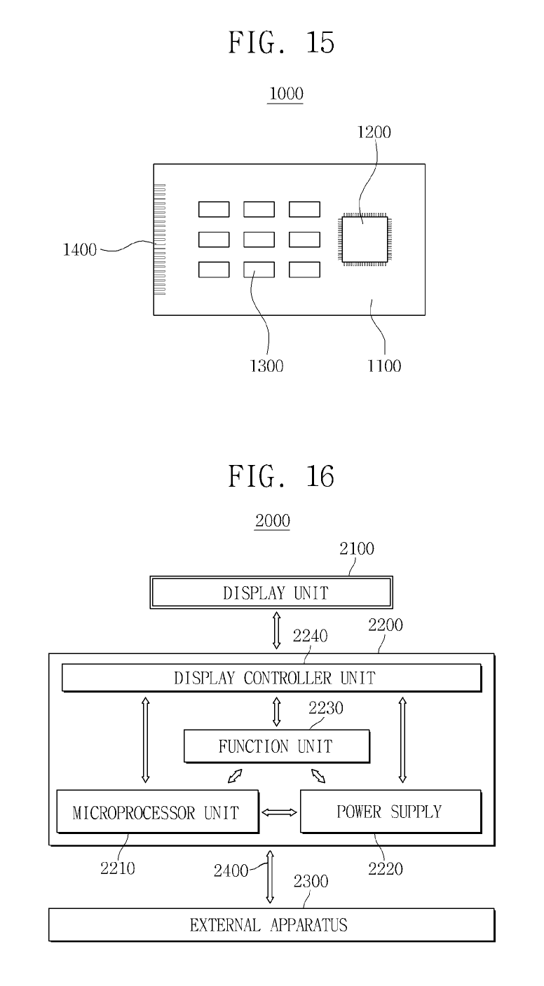

FIG. 15 is a schematic view showing a semiconductor module including a semiconductor package according to embodiments. Referring to FIG. 15, a semiconductor module 1000 may include a module substrate 1100, a memory 1200, a microprocessor 1300 and input/output terminals 1400. The memory 1200 and the microprocessor 1300 may be mounted on the module substrate 1100. The memory 1200 may include a semiconductor package according to one or more embodiments described herein. As such, reliability of the semiconductor module 1000 may be increased. The semiconductor module 1000 may include a memory card or a card package.

FIG. 16 is a block diagram showing an electronic device including a semiconductor package according to embodiments. Referring to FIG. 16, an electronic device 2000 may include a display unit 2100, a body 2200, and an external apparatus 2300. The body 2200 may be a system board a mother board, or the like including a printed circuit board (PCB). The body 2200 may include a microprocessor unit 2210, a power unit 2220, a function unit 2230, and a display controller unit 2240. The microprocessor unit 2210, the power unit 2220, the function unit 2230, and the display controller unit 2240 may be mounted or equipped on the body 2200. The microprocessor unit 2210 may be configured to receive voltage from the power unit 2220 to control the function unit 2230 and the display controller unit 2240. The power unit 2220 may be configured to receive a constant voltage from an external power source, an internal power source, or the like. The power unit 2220 may be configured to generate various voltage levels from the voltage level of the constant voltage. The power unit 2220 may be configured to provide voltages corresponding to the various voltage levels, to the microprocessor unit 2210, the function unit 2230 and the display controller unit 2240, or the like. The function unit 2230 may be configured to perform various functions of the electronic device 2000. For example, the function unit 2230 may include various elements capable of performing functions associated with wireless communication, such as outputting an image to the display unit 2100, using a voice output to a speaker in connection with dialing, operating an external apparatus 2300, or the like. When the electronic device 2000 includes a camera, the function unit 2230 can function as an image processor. The microprocessor unit 2210 and the function unit 2230 may include a semiconductor device according to one or more embodiments described herein, for processing various signals. Accordingly, reliability of the electronic device 2000 may be increased. The display unit 2100 may be located on a surface of one side portion of the body 2200. The display unit 2100 may be connected with the body 2200. The display unit 2100 may implement a processed image by the display controller unit 2240 of the body 2200. The electronic device 2000 may be connected with a memory card, or other memory device for expanded capacity. In this case, the function unit 2230 may include a memory card controller. The function unit 2230 may send a signal to the external apparatus 2300 and receive a signal from the external apparatus 2300 through a wire or wireless communication unit 2400. Also, the electronic device 2000 may include a universal serial bus (USB), etc. for function expansion. In this case, the function unit 2230 may function as an interface controller.

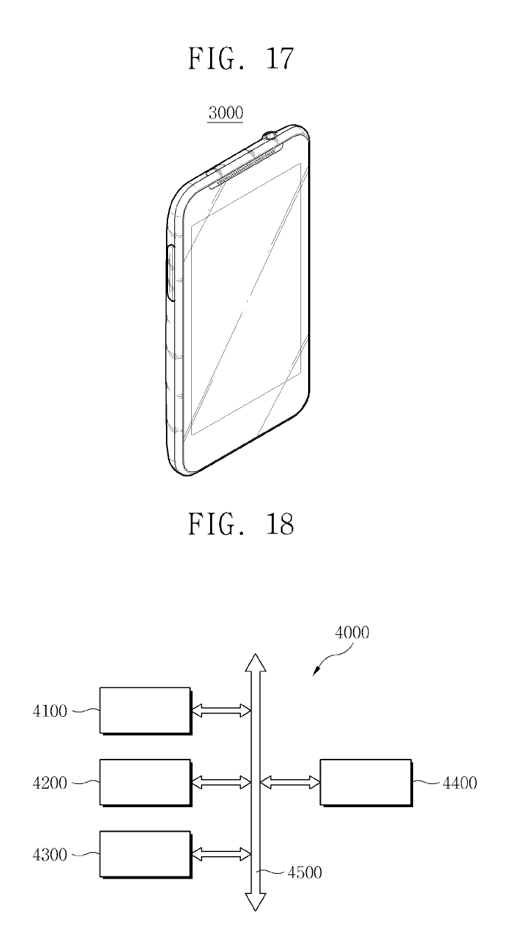

FIG. 17 is a perspective view showing a mobile device including a semiconductor package according to embodiments. Referring to FIG. 17, a mobile device 3000 may be a mobile wireless phone. The mobile device 3000 may be understood as a tablet PC. The mobile device 3000 may include a semiconductor device according to one or more embodiments described herein. As such, reliability of the mobile device 3000 may be increased.

FIG. 18 is a block diagram showing an electronic system including a semiconductor package according to embodiments. Referring to FIG. 18, an electronic system 4000 may include an interface 4100, a memory 4200, an input/output device 4300, and a controller 4400. The interface 4100 may be electrically connected with the memory 4200, the input/output device 4300, and the controller 4400 through the bus 4500. The interface 4100 may exchange data with an external system. The memory 4200 may include a semiconductor device according to one or more embodiments described herein. As such, reliability of the electronic system 4000 may be increased. The memory 4200 may be configured to store commands performed by the controller 4400 and/or data. The controller 4400 may include a microprocessor, a digital processor, or a microcontroller. The electronic system 4000 may include a personal digital assistant (PDA), a portable computer, a web tablet, a wireless phone, a mobile phone, a digital music player, or the like.

As described above, a semiconductor package and a method of fabricating the same according to an embodiment may use a support structure to prevent structural stability of the semiconductor package from deteriorating because of a load of semiconductor chips stacked offset on a circuit board. As a result, the semiconductor package and the method of fabricating the same according to an embodiment may be effective in stacking the semiconductor chips in great numbers on the circuit board without the deterioration of the structural stability of the semiconductor package.

Also, the semiconductor package and the method of fabricating the same according to an embodiment may use the support structure to connect input/output pads of the semiconductor chips to signal pads of the circuit board. As a result, the semiconductor package and the method of fabricating the same according to an embodiment may be effective in simplifying stacking the semiconductor chips on a circuit board regardless of the locations of the stacked semiconductor chips.

Further, the semiconductor package and the method of fabricating the same according to an embodiment may use the support structure to electrically connect the input/output pads of the semiconductor chips to the signal pads of the circuit board. As a result, the semiconductor package and the method of fabricating the same according to an embodiment may be effective in improving reliability in electrical connection of the semiconductor chips regardless of the locations of the stacked semiconductor chips.

Furthermore, the semiconductor package and the method of fabricating the same according to an embodiment may use the support structure to stack the semiconductor chips in order of the input/output pads to be aligned (e.g., vertically aligned) with the signal pads of the circuit board. As a result, the semiconductor package and the method of fabricating the same according to an embodiment may be effective in increasing an available area of the circuit board for stacking semiconductor chips.

Some embodiments provide a semiconductor package suitable for stacking a number of semiconductor chips on a printed circuit board without deterioration of structural stability, and a method of fabricating the same.

Other embodiments provide a semiconductor package suitable for simply stacking semiconductor chips regardless of locations of the stacked semiconductor chips, and a method of fabricating the same.

Still other embodiments provide a semiconductor package capable of increasing reliability of electrical connection of stacked semiconductor chips, and a method of fabricating the same.

Yet other embodiments provide a semiconductor package capable of increasing an available area of a printed circuit board on which semiconductor chips are stacked, and a method of fabricating the same.

In an embodiment, a semiconductor package includes a circuit board including a first signal pad and a second signal pad located on a first surface thereof; a first semiconductor chip mounted on the first surface of the circuit board and including a first input/output pad facing the first signal pad; a second semiconductor chip being stacked offset on the first semiconductor chip and including a second input/output pad vertically aligned with the second signal pad; and a support structure located between the second signal pad and the second input/output pad. The support structure includes a lower pad facing the second signal pad, an upper pad facing the second input/output pad, an insulating body located between the lower pad and the upper pad, and a conductive pillar penetrating the insulating body to electrically connect the lower pad and the upper pad.

The semiconductor package may further include a first connection element located between the upper pad and the second input/output pad; a second connection element located between the second signal pad and the lower pad; and a third connection element located between the first signal pad and the first input/output pad. The first connection element is in direct contact with the insulating body and the second semiconductor chip, and the second connection element is in direct contact the circuit board and the insulating body.

The third connection element may include the same material as the first connection element.

A thickness of the third connection element may be the same as a thickness of the first connection element.

The semiconductor package may further include a molding element covering the first semiconductor chip and the second semiconductor chip. The molding element may surround the first connection element, the second connection element and the third connection element.

The molding element fills spaces between the circuit board and the support structure, between the circuit board and the first semiconductor chip, between the support structure and the second semiconductor chip, and between the support structure and the first semiconductor chip.

The semiconductor package may further include a first chip magnetic pad located on the first input/output pad; and a second chip magnetic pad located on the second input/output pad.

A level of a lower surface of the first chip magnetic pad may be lower than that of a lower surface of the first semiconductor chip, and a level of a lower surface of the second chip magnetic pad may be lower than that of a lower surface of the second semiconductor chip.

A level of an upper surface of the first signal pad may be the same as that of an upper surface of the circuit board, and a level of an upper surface of the upper pad may be the same as that of an upper surface of the insulating body.

The semiconductor package may further include a first anisotropic conductive element located between the first signal pad and the first chip magnetic pad; and a second anisotropic conductive element located between the upper pad and the second chip magnetic pad.

The semiconductor package may further include a solder ball located between the second signal pad and the lower pad.

In an embodiment, a semiconductor package includes a circuit board including signal pads located on an upper surface thereof; semiconductor chips stacked in a terraced configuration on the upper surface of the circuit board, and including input/output pads located on lower surfaces of the semiconductor chips and vertically aligned with the signal pads, respectively; a support structure including conductive pillars located between the signal pads and the input/output pads of the semiconductor chips, and an insulating body surrounding the conductive pillars; and a molding element covering the semiconductor chips and the support structure. Each of the input/output pads of the semiconductor chips is electrically connected to the corresponding part of the signal pads by one of the conductive pillars.

The insulating body may be harder than the molding element.

An upper surface of the insulating body may have a terraced shape including step surfaces facing exposed lower surfaces of the stacked semiconductor chips, each of the conductive pillars may penetrate the insulating body disposed under the step surface facing the corresponding input/output pad.

The semiconductor package may further include adhesive layers located respectively on the lower surfaces of the semiconductor chips. A height difference between two neighboring step surfaces may be the same as the sum of a thickness of the corresponding semiconductor chip and a thickness of the corresponding adhesive layer.

An embodiment includes a method including attaching a support structure to a circuit board including a plurality of pads; attaching a first semiconductor chip to the circuit board such that a pad of the first semiconductor chip is aligned with a corresponding pad of the circuit board; and attaching a plurality of second semiconductor chips, each second semiconductor chip attached offset from an adjacent first or second semiconductor chip such that a pad of the second semiconductor chip aligns with a corresponding pad of the circuit board through the support structure.

Attaching the plurality of second semiconductor chips may include, for each second semiconductor chip: aligning the pad of the second semiconductor chip with the corresponding pad of the circuit board; and attaching the second semiconductor chip to a corresponding first or second semiconductor chip with an adhesive layer.

Attaching the plurality of second semiconductor chips may include, for each second semiconductor chip: attaching a connection element to the pad of the second semiconductor chip; and electrically connecting the pad of the second semiconductor chip to the corresponding pad of the circuit board through the support structure.

Accordingly, these and other changes and modifications are seen to be within the true spirit and scope of the invention as defined by the appended claims. It will be apparent to those skilled in the art that modifications and variations can be made in the inventive concepts without deviating from the spirit or scope of the invention. Thus, it is intended that the inventive concepts cover any such modifications and variations of this invention provided they come within the scope of the appended claims and their equivalents. Accordingly, these and other changes and modifications are seen to be within the true spirit and scope of the invention as defined by the appended claims.

What is claimed is:

1. A semiconductor package comprising:
a circuit board including a first pad and a second pad located on a first surface thereof;
a first semiconductor chip mounted on the first surface of the circuit board and including a third pad facing the first pad;
a second semiconductor chip being stacked offset on the first semiconductor chip and including a fourth pad aligned with the second pad; and
a support structure located between the second pad and the fourth pad,
wherein the support structure includes a fifth pad facing the second pad, a sixth pad facing the fourth pad, an insulating body located between the fifth pad and the sixth pad, and a conductive pillar penetrating the insulating body to electrically connect the fifth pad and the sixth pad.

2. The semiconductor package of claim 1, further comprising:
a first connection element located between the sixth pad and the fourth pad;
a second connection element located between the second pad and the fifth pad; and
a third connection element located between the first pad and the third pad,
wherein the first connection element is in direct contact with the insulating body and the second semiconductor chip, and the second connection element is in direct contact the circuit board and the insulating body.

3. The semiconductor package of claim 2, further comprising a molding element covering the first semiconductor chip and the second semiconductor chip,
wherein the molding element covers the first connection element, the second connection element and the third connection element.

4. The semiconductor package of claim 3, wherein the molding element fills spaces between the circuit board and the support structure, between the circuit board and the first semiconductor chip, between the support structure and the second semiconductor chip, and between the support structure and the first semiconductor chip.

5. The semiconductor package of claim 1, further comprising:
a first chip magnetic pad located on the third pad; and
a second chip magnetic pad located on the fourth pad.

6. The semiconductor package of claim 5, wherein a level of a bottom surface of the first chip magnetic pad is lower than that of a bottom surface of the first semiconductor chip, and a level of a bottom surface of the second chip magnetic pad is lower than that of a bottom surface of the second semiconductor chip.

7. The semiconductor package of claim 5, further comprising:
a first anisotropic conductive element located between the first pad and the first chip magnetic pad; and
a second anisotropic conductive element located between the sixth pad and the second chip magnetic pad.

8. A semiconductor package comprising:
a circuit board including a plurality of first pads located on a top surface thereof;
semiconductor chips stacked in a cascade configuration on the top surface of the circuit board, and including a plurality of second pads located on bottom surfaces of the semiconductor chips and vertically aligned with the first pads, respectively;
a support structure including conductive pillars located between the first pads and the second pads of the semiconductor chips, and an insulating body surrounding the conductive pillars; and
a molding element covering the semiconductor chips and the support structure,
wherein each of the second pads of the semiconductor chips is electrically connected to a corresponding first pad by one of the conductive pillars.

9. The semiconductor package of claim 8, wherein a top surface of the insulating body has a terraced shape including step surfaces facing exposed bottom surfaces of the stacked semiconductor chips, and each of the conductive pillars penetrates the insulating body disposed under the step surface facing the corresponding second pad.

10. The semiconductor package of claim 9, further comprising adhesive layers located respectively on the bottom surfaces of the semiconductor chips,
wherein a height difference between two neighboring step surfaces is substantially the same as the sum of a thickness of the corresponding semiconductor chip and a thickness of the corresponding adhesive layer.

11. A semiconductor package, comprising:
a circuit board including a plurality of pads;
a support structure disposed on the circuit board; and
a plurality of semiconductor chips stacked on the circuit board and the support structure, each semiconductor chip including at least one pad;
wherein for each semiconductor chip:
the at least one pad is aligned with a corresponding pad of the circuit board; and
an electrical connection is formed between the at least one pad and the corresponding pad of the circuit board through the support structure.

12. The semiconductor package of claim 11, wherein the semiconductor chips referred to as first semiconductor chips, the semiconductor package further comprising:
a second semiconductor chip disposed on the circuit board and including a pad electrically connected to a pad of the circuit board outside of the support structure.

13. The semiconductor package of claim 12, wherein:
the first semiconductor chips are substantially same chip; and
the second semiconductor chip is different from the first semiconductor chips.

14. The semiconductor package of claim 12, further comprising a chip supporting element disposed between the lowest one of the first semiconductor chips and the circuit board.

15. The semiconductor package of claim 11, wherein the support structure comprises a plurality of conductive pillars, each conductive pillar electrically coupled between a corresponding pad of the circuit board and a corresponding pad of one of the semiconductor chips.

16. The semiconductor package of claim 11, wherein the support structure comprises:
a plurality of first pads; and
a plurality of second pads;
wherein:
the first pads are disposed on a first surface of the support structure;
the second pads are disposed on at least one second surface opposite the first surface; and
each first pad is electrically connected to a corresponding second pad through the support structure.

17. The semiconductor package of claim 16, further comprising:
a plurality of first connection elements, each first connection element electrically connecting a corresponding first pad and a corresponding pad of the circuit board; and
a plurality of second connection elements each second connection element electrically connecting a corresponding second pad and a corresponding pad of one of the semiconductor chips.

18. The semiconductor package of claim 16, wherein:
for each first pad, a surface of the first pad is substantially coplanar with the first surface; and
for each second pad, a surface of the second pad is substantially coplanar with the corresponding second surface.

19. The semiconductor package of claim 11, wherein the support structure has a stepped structure including multiple surfaces and each semiconductor is coupled to a different surface of the stepped structure.

20. The semiconductor package of claim 11, wherein:
the support structure includes a plurality of sub support structure, the electrical connection being formed between the at least one pad of the first semiconductor chip and the corresponding pad of the circuit board through one of the sub support structure,
wherein the plurality of the sub structure is spaced each other, and a height of the plurality of the sub structure is different each other.
